(19) United States
(12) Patent Application Publication
(10) Pub. No.: US 2024/0021751 A1
(43) Pub. Date: Jan. 18, 2024

(54) LED MODULE, METHOD OF MANUFACTURING THE SAME, AND LED DISPLAY APPARATUS

(71) Applicant: SAMSUNG ELECTRONICS CO,. LTD., Suwon-si (KR)

(72) Inventors: Jihye Yeon, Suwon-si (KR); Hankyu Seong, Suwon-si (KR); Sunghyun Sim, Suwon-si (KR); Donggun Lee, Suwon-si (KR); Youngjin Choi, Suwon-si (KR)

(73) Assignee: SAMSUNG ELECTRONICS CO,. LTD., Suwon-si (KR)

(21) Appl. No.: 18/222,296

(22) Filed: Jul. 14, 2023

(30) Foreign Application Priority Data
Jul. 15, 2022 (KR) 10-2022-0087472
Feb. 24, 2023 (KR) 10-2023-0024820

(51) Int. Cl. H01L 33/00; H01L 33/06; H01L 33/08

(52) U.S. Cl. CPC H01L 33/0093; H01L 33/06; H01L 33/08; H01L 33/325

(57) ABSTRACT

A method of manufacturing an LED module includes forming a first conductivity-type semiconductor base layer on a growth substrate; forming a mask pattern having first to third openings on the first conductivity-type semiconductor base layer, wherein the mask pattern the first to the third openings having different widths and arranged with a same pitch; simultaneously forming first to third light emitting laminates in the first to third openings, respectively; removing the mask pattern from the first conductivity-type semiconductor base layer; and removing an edge region of each of the first to third light emitting laminates, wherein first to third light emitting laminates include a first to third active layers configured to emit light of different wavelengths, respectively.

### CROSS-REFERENCE TO RELATED APPLICATIONS

This application claims priority to Korean Patent Application No. 10-2022-0087472 filed on Jul. 15, 2022 and Korean Patent Application No. 10-2023-0024820 filed on Feb. 24, 2023 in the Korean Intellectual Property Office, the disclosures of each of which being incorporated by reference herein in their entireties.

### BACKGROUND

Example embodiments relate to an LED module, a method of manufacturing the same, and an LED display apparatus.

A semiconductor light emitting diode (LED) has been used as a light source for a light source for lighting devices and various electronic products. Also, an LED has been widely used as a light source for various display devices such as a TV, a mobile phone, a PC, a laptop PC, and a PDA.

A related art display device may mainly consist of a display panel including liquid crystal displays (LCD) and a backlight, but recently, LEDs may be used as pixels such that a backlight may not be necessary. A display apparatus using LEDs as pixels may be miniaturized, and may also implement a display apparatus having high brightness and excellent light efficiency as compared to an LCD.

### SUMMARY

It is an aspect to provide an LED module having high efficiency which may be manufactured by a simplified process, and a method of manufacturing the same.

It is another aspect to provide a display apparatus having high efficiency which may be manufactured by a simplified process.

According to an aspect of one or more example embodiments, there is provided a method comprising forming a first conductivity-type semiconductor base layer on a growth substrate; forming a mask pattern on the first conductivity-type semiconductor base layer, wherein the mask pattern has a first opening, a second opening and a third opening having different widths, and the first opening, the second opening and the third opening are arranged with a same pitch; simultaneously forming a first light emitting laminate, a second light emitting laminate, and a third light emitting laminate in the first opening, the second opening, and the third opening, respectively, by sequentially growing a first active layer, a second active layer, and a third active layer and second conductivity-type semiconductor layers on regions of the first conductivity-type semiconductor base layer opened by the first opening, the second opening, and the third opening, respectively; removing the mask pattern from the first conductivity-type semiconductor base layer; and removing an edge region of each of the first light emitting laminate, the second light emitting laminate, and the third light emitting laminate, wherein forming the first light emitting laminate, the second light emitting laminate, and the third light emitting laminate is performed by a same growth process, and the first active layer, the second active layer, and the third active layer have a first quantum well layer, a second quantum well layer, and a third quantum well layer emitting light of different wavelengths, respectively.

According to another aspect of one or more example embodiments, there is provided a method comprising forming a first conductivity-type semiconductor base layer on a growth substrate; forming a first mask pattern on the first conductivity-type semiconductor base layer, wherein the first mask pattern has a first opening and a second opening having different widths, and the first opening and the second opening are arranged with a first pitch; simultaneously growing a first active layer and a second active layer on a first region and a second region of the first conductivity-type semiconductor base layer opened by the first opening and the second opening, respectively, wherein the first active layer and the second active layer respectively include a first quantum well layer and a second quantum well layer emitting a first light and a second light of different wavelengths, respectively; forming a second mask pattern covering the first opening and the second opening, the second mask pattern having a third opening configured to open a third region of the first conductivity-type semiconductor base layer, wherein the third opening is arranged with a second pitch with an adjacent opening among the first opening and the second opening, and the second pitch is the same as the first pitch; forming a third active layer in the third region of the first conductivity-type semiconductor base layer, wherein the third active layer includes a third quantum well layer configured to emit third light of a wavelength different from wavelengths of each of the first light and the second light; forming a fourth opening and a fifth opening exposing the first active layer and the second active layer, respectively, in the second mask pattern; forming a first light emitting laminate, a second light emitting laminate, and a third light emitting laminate by growing a second conductivity-type semiconductor layer on each of the first active layer, the second active layer, and the third active layers; removing the first mask pattern and the second mask pattern from the first light emitting laminate, the second light emitting laminate, and the third light emitting laminate and the first conductivity-type semiconductor base layer; and removing an edge region of each of the first light emitting laminate, the second light emitting laminate, and the third light emitting laminate.

According to yet another aspect of one or more example embodiments, there is provided a method comprising forming a first conductivity-type semiconductor base layer on a growth substrate; forming a mask pattern having a first opening, a second opening, and a third opening arranged with a same pitch on the first conductivity-type semiconductor base layer, wherein the first opening has a first width, the second opening has a second width, and the third opening has a third width, and the first width is greater than the second width, and the first width is the same as the third width; forming a first light emitting laminate, a second light emitting laminate, and a third light emitting laminate in the first opening, the second opening, and the third opening, respectively, by sequentially growing a first active layer, a second active layer, and a third active layer and second conductivity-type semiconductor layers on regions of the first conductivity-type semiconductor base layer opened by the first opening, the second opening, and the third opening, respectively; removing the mask pattern from the first conductivity-type semiconductor base layer; and removing an edge region of each of the first light emitting laminate, the second light emitting laminate, and the third light emitting laminate, wherein forming the first light emitting laminate, the second light emitting laminate, and the third light emitting laminate is performed by a same growth process, the first active layer and the third active layer include a first quantum well layer and a third quantum well layer emitting light of a same wavelength, respectively, and the second active layer includes a second quantum well layer configured to emit light of a different wavelength from the same wavelength of the first quantum well layer and the third quantum well layer.

According to yet another aspect of one or more example embodiments, there is provided an LED module comprising a first conductivity-type semiconductor base layer; and a first LED cell, a second LED cell, and a third LED cell arranged with a same pitch on the first conductivity-type semiconductor base layer and including semiconductor layers corresponding to each other, wherein each of the first LED cell, the second LED cell, and the third LED cell includes a nitride single crystal laminate in which a first conductivity-type cap layer, an active layer and a second conductivity-type semiconductor layer are sequentially laminated, and the nitride single crystal laminate has an upper surface which is a (0001) plane and a side surface that is perpendicular to the first conductivity-type semiconductor base layer, and wherein the active layer of the first LED cell includes a first quantum well layer configured to emit light of a wavelength of 440 nm to 480 nm, the active layer of the second LED cell includes a second quantum well layer configured to emit light of a wavelength of 510 nm to 550 nm, the active layer of the third LED cell includes a third quantum well layer configured to emit light having a wavelength of 610 nm to 650 nm, and the first quantum well layer, the second quantum well layer, and the third quantum well layer include nitride single crystal layers satisfying InxGa1-xN having different contents of indium (x), respectively.

According to yet another aspect of one or more example embodiments, there is provided a display apparatus comprising a circuit board having a driver circuit; and a pixel array disposed on the circuit board and including pixel units each including a first sub-pixel, a second sub-pixel, and a third sub-pixel arranged therein. The pixel array includes a first conductivity-type semiconductor base layer having a first surface facing the circuit board and a second surface opposite to the first surface; a plurality of first LED cells arranged to correspond to the first sub-pixels, a plurality of second LED cells arranged to correspond to the second sub-pixels, and a plurality of third LED cells arranged to correspond to the third sub-pixels on the first surface of the first conductivity-type semiconductor base layer, and each of the plurality of first LED cells, each of the plurality of second LED cells, and each of the plurality of third LED cells including a first conductivity-type semiconductor cap layer, an active layer, and a second conductivity-type semiconductor layer stacked in order; a light blocking partition structure disposed on the second surface of the first conductivity-type semiconductor base layer and having light emitting windows corresponding to the first sub-pixels, the second sub-pixels, and the third sub-pixels, respectively; a passivation layer disposed on the first surface of the first conductivity-type semiconductor base layer and side surfaces and upper surfaces of the plurality of first LED cells, the plurality of second LED cells, and the plurality of third LED cells; a first electrode disposed on the passivation layer and electrically connected to the first conductivity-type semiconductor base layer of each of the plurality of first LED cells, the plurality of second LED cells, and the plurality of third LED cells; and second electrodes disposed on the passivation layer and electrically connected to the second conductivity-type semiconductor layers of the plurality of first LED cells, the plurality of second LED cells, and the plurality of third LED cells, respectively, wherein the plurality of first LED cells, the plurality of second LED cells, and the plurality of third LED cells have an upper surface which is a (0001) plane and a side surface that is perpendicular to the first surface of the first conductivity-type semiconductor base layer.

### BRIEF DESCRIPTION OF DRAWINGS

The above and other aspects will be more clearly understood from the following detailed description, taken in combination with the accompanying drawings, in which:

FIG. 1 is a perspective diagram illustrating a display apparatus according to some example embodiments;

FIG. 2 is a plan diagram illustrating a display apparatus according to some example embodiments;

FIG. 3 is a cross-sectional diagram illustrating a display apparatus according to some example embodiments;

FIGS. 4A and 4B are a cross-sectional diagram and a plan diagram, respectively, illustrating an LED module employed in a display apparatus according to some example embodiments;

FIG. 5 is a diagram illustrating a driver circuit implemented in a display apparatus according to some example embodiments;

FIGS. 6A to 6E are cross-sectional diagrams illustrating processes of a method of manufacturing an LED module according to some example embodiments;

FIG. 7 is a plan diagram illustrating the LED module illustrated in FIG. 6E;

FIGS. 8A and 8B are cross-sectional diagrams illustrating processes of a method of manufacturing an LED module according to some example embodiments;

FIG. 9 is a plan diagram illustrating the LED module illustrated in FIG. 8B;

FIG. 10 is a plan diagram illustrating an LED module according to some example embodiments;

FIGS. 11A to 11F are cross-sectional diagrams illustrating a portion of processes of a method of manufacturing a display apparatus according to some example embodiments;

FIGS. 12A to 12D are cross-sectional diagrams illustrating a portion of processes of a method of manufacturing a display apparatus according to some example embodiments;

FIG. 13 is a cross-sectional diagram illustrating a display apparatus according to some example embodiments;

FIGS. 14A and 14B are cross-sectional diagrams illustrating a display apparatus according to some example embodiments;

FIGS. 15A to 15F are cross-sectional diagrams illustrating a portion of processes of a method of manufacturing a display apparatus according to some example embodiments;

FIGS. 16A to 16D are cross-sectional diagrams illustrating a portion of processes of a method of manufacturing a display apparatus according to some example embodiments; and

FIG. 17 is a diagram illustrating an electronic device including a display apparatus according to some example embodiments.

### DETAILED DESCRIPTION

Hereinafter, various example embodiments will be described with reference to the accompanying drawings.

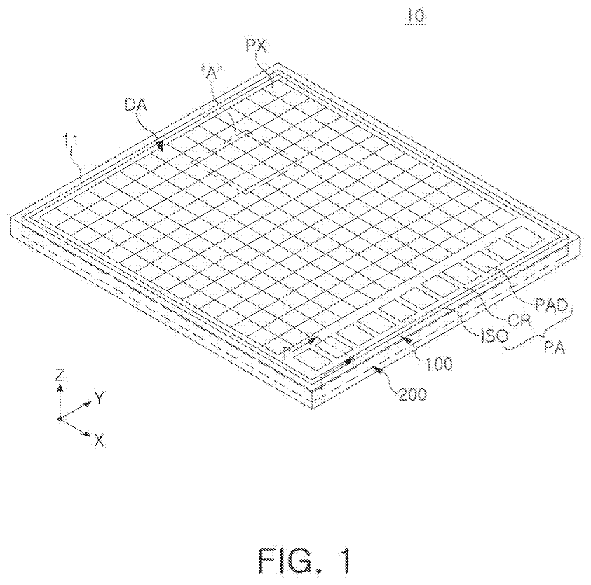

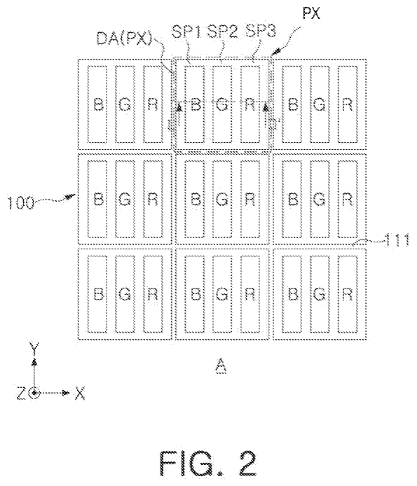

FIG. 1 is a perspective diagram illustrating a display apparatus according to some example embodiments. FIG. 2 is a plan diagram illustrating a display apparatus according to some example embodiments. FIG. 2 illustrates a portion ‘A’ of the display apparatus of FIG. 1.

Referring to FIGS. 1 and 2, the display apparatus 10 may include a circuit board 200 including driver circuits, and a pixel array 100 disposed on the circuit board 200 and having a plurality of pixels PX arranged thereon. The display apparatus 10 may further include a frame 11 surrounding the circuit board 200 and the pixel array 100.

The circuit board 200 may include a driver circuit including thin film transistor (TFT) cells. In some example embodiments, the circuit board 200 may further include other circuits in addition to the driver circuits for the display apparatus. In some example embodiments, the circuit board 200 may include a flexible substrate, and the display apparatus may be implemented as a display apparatus having a curved profile.

The pixel array 100 may include a display area DA and a peripheral area PA on at least one side of the display area DA. The display area DA may include an LED module for display. The pixel array 100 may include a display area DA in which a plurality of pixels PX are arranged. The peripheral area PA may include a pad region PAD, a connection region CR connecting a plurality of pixels PX to the pad regions PAD, and an outer region ISO.

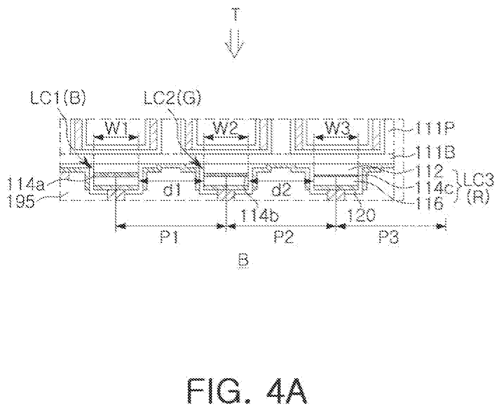

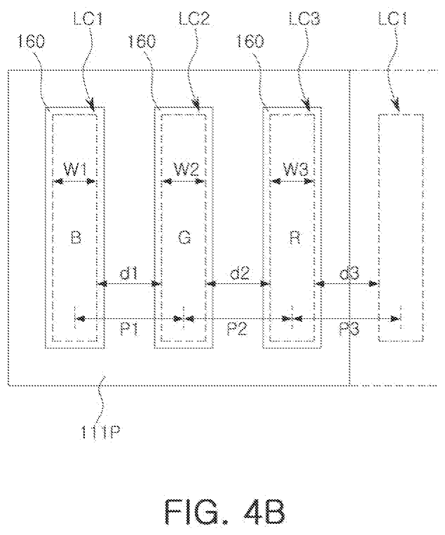

Each of the plurality of pixels PX may include a first sub-pixel SP1, a second sub-pixel SP2, and a third sub-pixel SP3 configured to emit light of a specific wavelength, for example, a specific color, to provide a color image. For example, the first to third sub-pixels SP1, SP2, and SP3 may be configured to emit blue (B) light, green (G) light, and red (R) light, respectively. The pixel array 100 may include an LED module configured to directly emit blue (B) light, green (G) light, and red (R) light without using an additional wavelength converter (see FIGS. 4A and 4B).

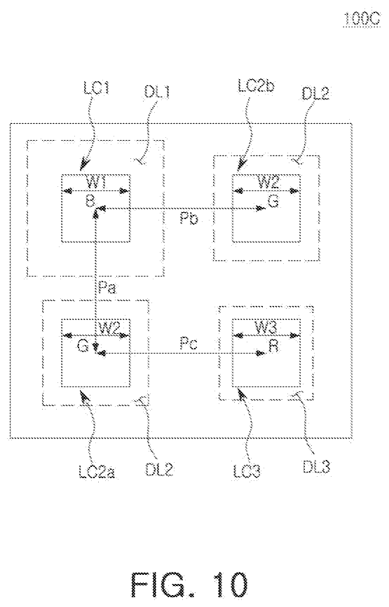

As illustrated in FIG. 2, in each pixel PX (or a pixel unit), first to third sub-pixels SP1, SP2, and SP3 may have a pattern in which the sub-pixels are arranged side by side in one direction (e.g., an X direction). However, example embodiments are not limited thereto, and in some example embodiments, first to third sub-pixels SP1, SP2, and SP3 may be arranged in other patterns such as a Bayer pattern (e.g., see FIG. 10). In some example embodiments, each pixel PX may be configured in a different arrangement, such as 3×3 or 4×4.

In the pixel array 100 in FIG. 1, a plurality of pixels PX may be arranged in a 15×15 array, but the number of rows and columns may be any suitable number, for example, 11,024×768. For example, depending on desired resolution, the plurality of pixels PX may have different arrangements.

The pad regions PAD may be disposed on at least one side of the plurality of pixels PX along an edge of the display apparatus 10. The pad regions PAD may be electrically connected to a plurality of pixels PX and driver circuits of the circuit board 200. The pad regions PAD may electrically connect an external device to the display apparatus 10. In some example embodiments, the number of pad regions PAD may be varied, and may be determined according to, for example, the number of pixels PX, a method of driving a TFT circuit in the circuit board 200, and the like.

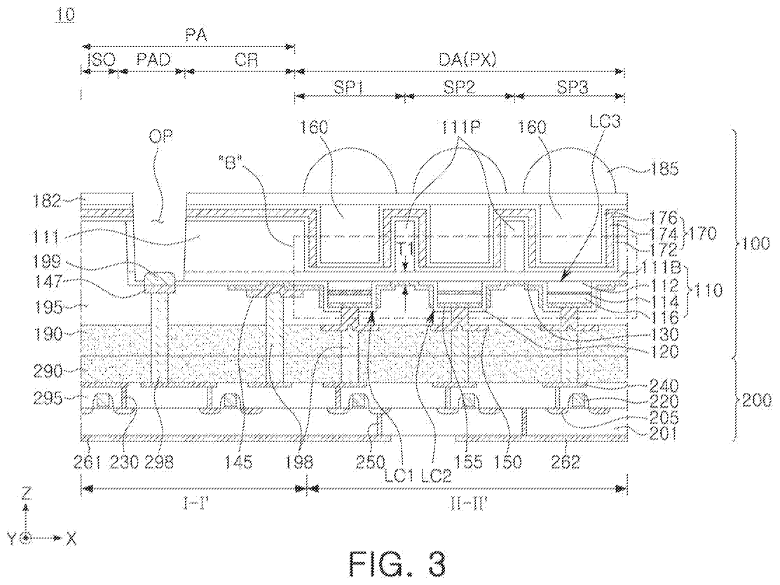

The connection region CR may be disposed between the plurality of pixels PX and the pad regions PAD. A wiring structure electrically connected to the plurality of pixels PX, for example, a common electrode, may be disposed in the connection region CR. The outer region ISO may be disposed along edges of the pixel array 100. In the outer region ISO, the upper semiconductor layer 111 may not be disposed (see FIG. 3).

The frame 11 may be arranged around the pixel array 100 to serve as a guide defining the arrangement space of the pixel array 100. The frame 11 may include, for example, at least one of materials such as polymers, ceramics, semiconductors, or metals. For example, the frame 11 may include a black matrix. However, the frame 11 is not limited to a black matrix, and in some example embodiments, the frame 11 may include a white matrix or a structure of another color depending on the purpose of the display apparatus 10. For example, the white matrix may include a reflective material or a scattering material. The display apparatus 10 in FIG. 1 may have a rectangular planar structure, but example embodiments are not limited thereto and, in some example embodiments, the display apparatus 10 may have other shapes.

FIG. 3 is a cross-sectional diagram illustrating a display apparatus according to some example embodiments. FIG. 3 illustrates a combination of a cross-section (the peripheral area PA) taken along IT in FIG. 1 and a cross-section (the display area DA) taken along II-II in FIG. 2.

Referring to FIG. 3, the display apparatus 10 may include a circuit board 200 and a pixel array 100 disposed on the circuit board 200.

The circuit board 200 may include a semiconductor substrate 201, a driver circuit including driving elements 220 including TFT cells formed on the semiconductor substrate 201, interconnection portions 230 electrically connected to the driving elements 220, wiring layers 240 on the interconnection portions 230, and a second bonding insulating layer 290 covering the driver circuit. In some example embodiments, the circuit board 200 may further include a second wiring insulating layer 295 on the second bonding insulating layer 290 and second bonding electrodes 298 disposed within the second wiring insulating layer 295 and connected to the wiring layers 240.

The pixel array 100 may include a display area in which a plurality of pixels PX are arranged, and each of the plurality of pixels PX may include first to third sub-pixels SP1, SP2, and SP3 arranged in a predetermined pattern (e.g., see FIG. 2).

The pixel array 100 may include an LED module implemented as a semiconductor laminate 110. The LED module in some example embodiments may include a first LED cell LC1, a second LED cell LC2, and a third LED cell LC3 for the first to third sub-pixels SP1, SP2, and SP3 without a wavelength converter. The first to third LED cells LC1, LC2, and LC3 may be micro-LEDs, and the LED cells may be configured to emit light of different wavelengths. Specifically, the LED module may include first to third LED cells LC1, LC2, and LC3 configured to directly emit blue (B) light, green (G) light, and red (R) light, respectively.

FIG. 4A is an enlarged cross-section diagram illustrating a portion “B” (LED module) of the display apparatus of FIG. 3, according to some example embodiments, and FIG. 4B is a plan diagram of the example in FIG. 4A, viewed in a “T” direction, illustrating a plan diagram illustrating an LED module corresponding to a pixel.

The semiconductor laminate 110 in some example embodiments may include a first conductivity-type semiconductor base layer 111B having a first surface facing the circuit board 200 and a second surface opposite thereto, and the first to third LED cells LC1, LC2, and LC3 placed on the first surface of the first conductivity-type semiconductor base layer 111B.

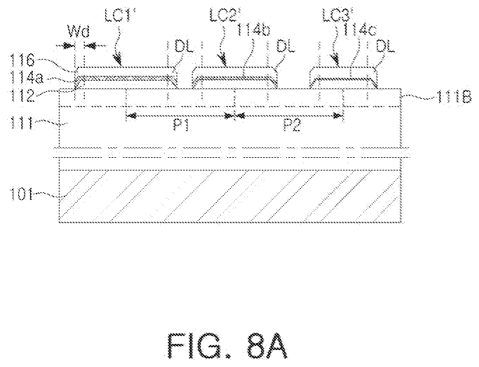

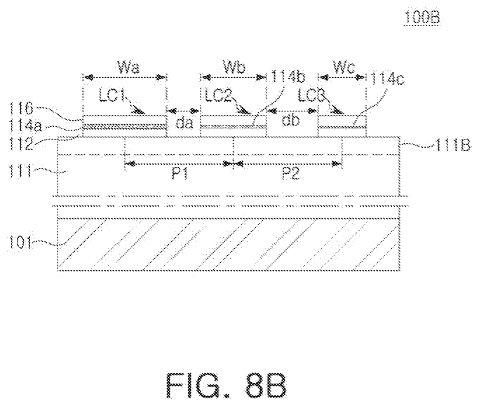

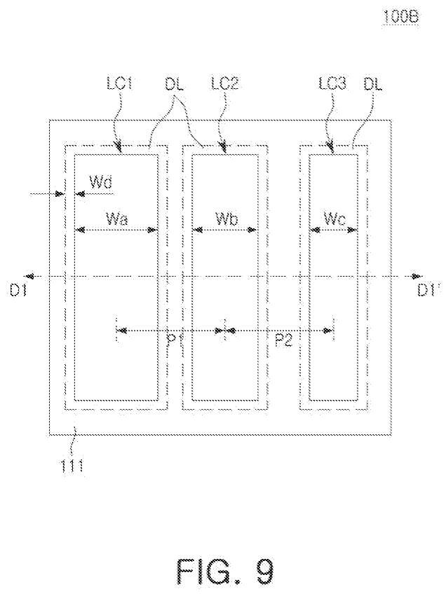

The first to third LED cells LC1, LC2, and LC3 included in each pixel PX may be arranged with the same pitch (P1=P2). Here, the pitch may be defined as a distance between centers of adjacent LED cells. In some example embodiments, a pitch P3 with an LED cell of another adjacent pixel PX may be the same the pitch P1 and P2 (i.e., P1=P2=P3). In some example embodiments, the first to third LED cells LC1, LC2, and LC3 may have the same width (W1=W2=W3) (or the same area (when viewed in plan view)) and the same distance (d1=d2). In some example embodiments, the distance d3 from the LED cell of another adjacent pixel PX may be the same as the distances d1 and d2 (i.e., d1=d2=d3). However, some example embodiments are not limited thereto, and in some example embodiments, the widths and/or distances of the first to third LED cells LC1, LC2, and LC3 may be different. For example, considering efficiency according to the wavelength of light, the width (or an area) of an LED cell having a relatively low efficiency may be configured to be large, and the distance with an LED cell adjacent thereto may be configured to be relatively narrow (FIG. 8B and see FIG. 9).

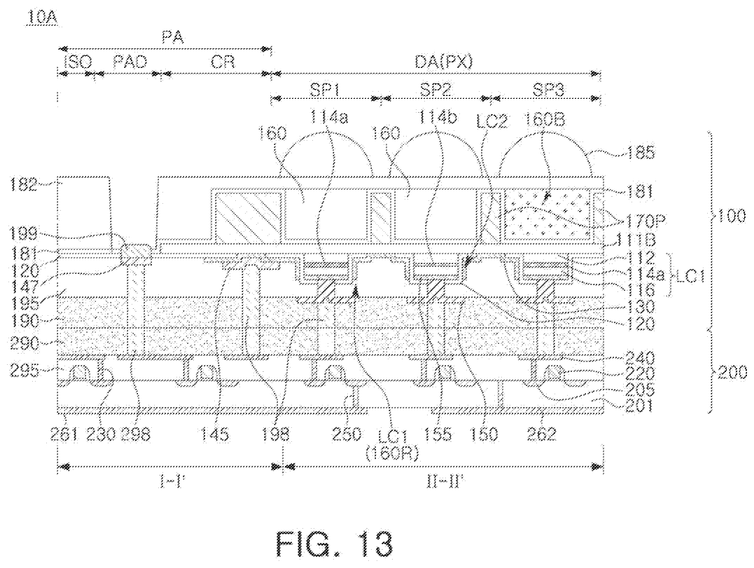

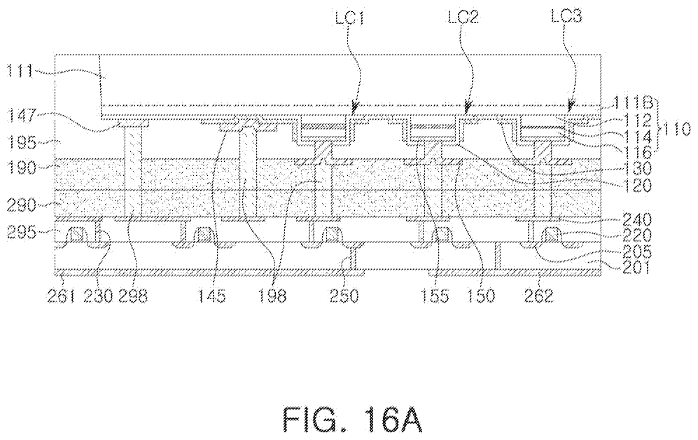

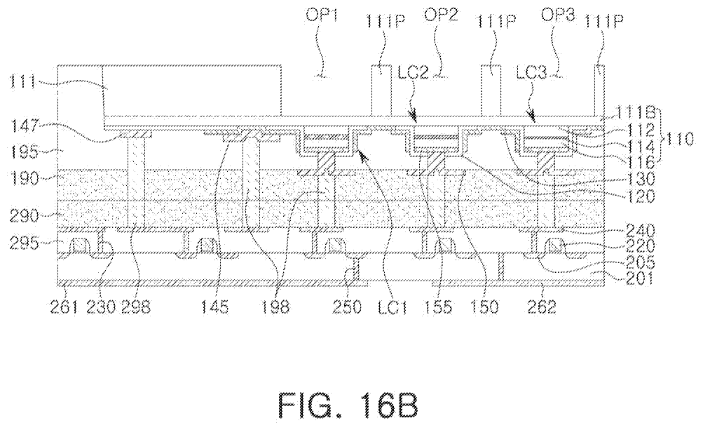

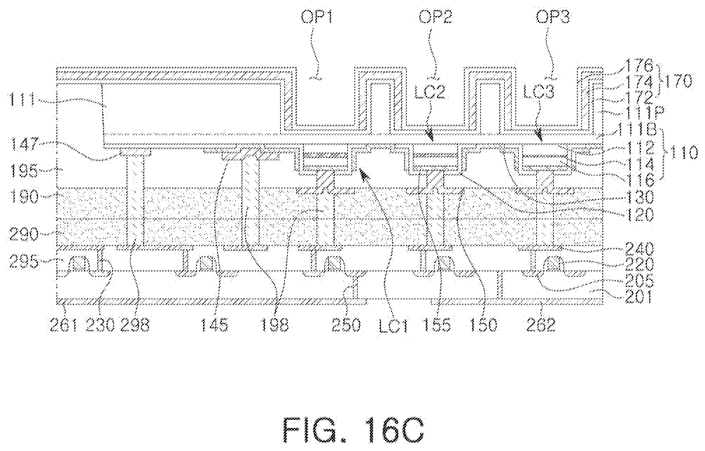

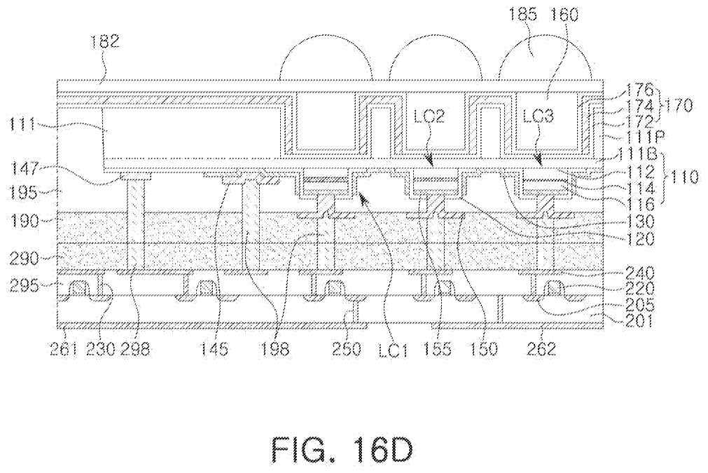

In some example embodiments, a partition structure 111P may be disposed on the second surface of the first conductivity-type semiconductor base layer 111B. For example, the partition structure 111P may be obtained by etching the semiconductor layer 111 (also referred to as an “under-semiconductor layer”) integrated with the first conductivity-type semiconductor base layer 111B (see FIG. 16B). The semiconductor layer 111 may be a first conductivity-type semiconductor layer or an undoped semiconductor layer, or may include a laminate of a first conductivity-type semiconductor layer and an undoped semiconductor layer. However, example embodiments are not limited thereto, and in some example embodiments, the partition structure may include a structure formed of another material (e.g., a light blocking material or a reflective material) (see FIG. 13).

The first to third LED cells LC1, LC2, and LC3 in some example embodiments may include a nitride single crystal laminate grown in the same growth process. Since the nitride single crystal laminate is formed by the same growth process, the layers may correspond to each other. As illustrated in FIG. 4A, the nitride single crystal laminate may include a first conductivity-type semiconductor cap layer 112 for each of the first to third LED cells LC1, LC2, and LC3, a first active layer 114a, a second active layer 114b, and a third active layer 114c respectively for the first to third LED cells LC1, LC2, and LC3, and a second conductivity-type semiconductor layer 116 for each of the first to third LED cells LC1, LC2, and LC3, stacked in order on the first surface of the first conductivity-type semiconductor base layer 111B.

The first conductivity-type semiconductor base layer 111B and the first conductivity-type semiconductor cap layer 112 may be a nitride semiconductor layer having a composition of n-type InₓAl_{y}Ga_{1-x-y}N(0≤x<1, 0≤y<1, 0≤x+y<1). For example, the first conductivity-type semiconductor cap layer 112 may be an n-type gallium nitride (n-GaN) layer doped with silicon (Si), germanium (Ge), or carbon (C). The second conductivity-type semiconductor layer 116 may be a nitride semiconductor layer having a composition of p-type Inₓ Al_{y}Ga_{1-x-y}N(0≤x<1, 0≤y<1, 0≤x+y<1). For example, the second conductivity-type semiconductor layer 116 may be a p-type gallium nitride (p-GaN) layer doped with magnesium (Mg) or zinc (Zn). Each of the first conductivity-type semiconductor cap layer 112 and the second conductivity-type semiconductor layer 116 may be formed as a single layer, or may include a plurality of layers having different characteristics such as different doping concentrations and compositions.

The first to third active layers 114a, 114b, and 114c may emit light having predetermined energy by recombination of electrons and holes. The first to third LED cells LC1, LC2, and LC3 in some example embodiments may include first to third active layers 114a, 114b, and 114c configured to emit light of different wavelengths, respectively. The active layer 114 may have a single quantum well (SQW) structure, or a multiple quantum well (MQW) structure in which quantum barrier layers and quantum well layers are alternately arranged.

In some example embodiments, since the first to third active layers 114a, 114b, and 114c are simultaneously formed by the same growth process, the active layers may also include layers corresponding to each other. For example, the first to third active layers 114a, 114b, and 114c may include the same number of quantum barrier layers and quantum well layers.

The first active layer 114a may include a first quantum well layer configured to emit blue light, for example, light having a wavelength of 440 nm to 480 nm. The second active layer 114b may include a second quantum well layer configured to emit green light, for example, light having a wavelength of 510 nm to 550 nm. The third active layer 114c may include a third quantum well layer configured to emit red light, for example, light having a wavelength of 610 nm to 650 nm.

The first to third quantum well layers may include InₓGa₁₋ₓN(0<x≤1) layers having different contents of indium (x). For example, the content of indium of the first quantum well layer may be in the range of 0.15-0.2, the content of indium of the second quantum well layer may be in the range of 0.25-0.3, and the content of indium of the third quantum well layer may be in the range of 0.3-0.35. For example, the quantum barrier layer may be GaN or AlGaN.

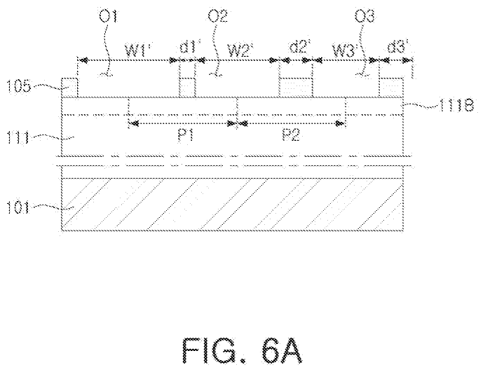

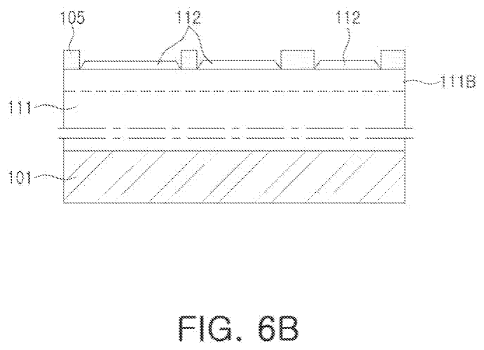

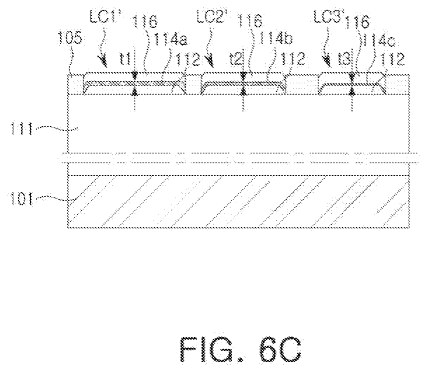

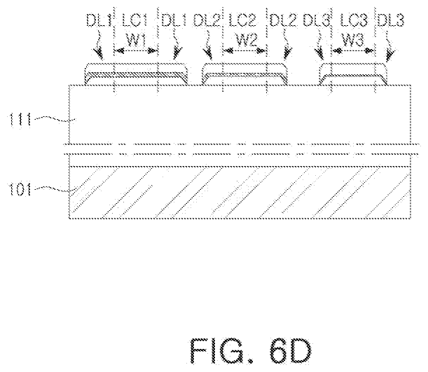

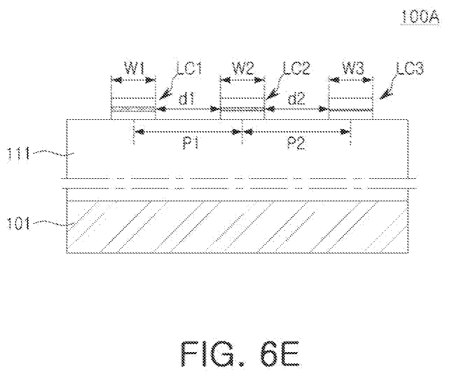

As described above, the first to third quantum well layers may be simultaneously formed in the same growth process, and a difference in content of indium may be induced by adjusting the area of the grown region for the first to third LED cells LC1, LC2, and LC3 and accordingly, the first to third LED cells LC1, LC2, and LC3 may be configured to emit light of different wavelengths (see FIGS. 6A to 6C).

In some example embodiments, the thickness t1 of the first active layer 114a may be greater than the thickness t2 of the second active layer 114b, and the thickness t2 of the second active layer 114b may be greater than the thickness t3 of the third active layer 114b (see FIG. 6C). Specifically, the thickness of the first quantum well layer may be greater than the thickness of the second quantum well layer, and the thickness of the second quantum well layer may be greater than the thickness of the third quantum well layer. For example, the thickness of the first quantum well layer may be in the range of 2.5 nm-4 nm, the thickness of the second quantum well layer may be in the range of 2.5 nm-3.5 nm, and the thickness of the third quantum well layer may be in the range of 2 nm-3 nm.

The first to third LED cells LC1, LC2, and LC3 in some example embodiments may include single crystal laminates 112, 114, and 116 having an upper surface, a (0001) plane, and a side surface substantially perpendicular to the first surface of the first conductivity-type semiconductor base layer 111B. For example, the upper surface of the second conductivity-type semiconductor layer 116 may be a (0001) plane. Side surfaces of the nitride single crystal laminates 112, 114, and 116 may have substantially vertical side surfaces obtained by removing edge regions causing leakage current through an etching process (see FIGS. 6E and 6F). For example, the angles of the side surfaces 112, 114, and 116 of the nitride single crystal laminate with respect to the first conductivity-type semiconductor base layer 111B may be in the range of 85° to 95°.

In some example embodiments, since the partition structure 111P dividing sub-pixels SP1, SP2, and SP3 may include a semiconductor layer 111 having light transmissivity, to prevent optical interference between the sub-pixels SP1, SP2, and SP3, a partition reflective layer 170 may be disposed on the surface thereof.

The partition reflective layer 170 in some example embodiments may be formed on the upper surface and side walls of the partition structure 111E As illustrated in FIG. 3, the partition reflective layer 170 in some example embodiments may include a first partition insulating film 172, a reflective metal film 174, and a second partition insulating film 176 stacked in order. The first partition insulating layer 172 and the second partition insulating layer 176 may include at least one of an insulating material, for example, SiO₂, SiN, SiCN, SiOC, SiON and SiOCN. The reflective metal film 174 may include at least one of reflective metals, for example, silver (Ag), nickel (Ni), and aluminum (Al). The reflective metal film 174 may be formed on inner sidewalls of the plurality of sub-pixel spaces, and may not be formed on the bottom surface thereof. Through the arrangement, light emitted from each of the LED cells LC1, LC2, and LC3 may be emitted from the bottom surface of the plurality of sub-pixel spaces. A transparent resin portion 160 may be formed in each sub-pixel space surrounded by the partition reflective layer 170. In some example embodiments, the transparent resin portion 160 may not include a wavelength conversion material such as a phosphor and/or a quantum dot, and light (e.g., R, G, B) of a wavelength required by each sub-pixel SP1, SP2, and SP3 may be emitted directly from the first to third LED cells LC1, LC2, and LC3. In some example embodiments, the transparent resin portion 160 may further include a light scattering material.

As illustrated in FIG. 3, the first conductivity-type semiconductor base layer 111B may be provided as a common layer shared by first to third LED cells LC1, LC2, and LC3 of the entirety of pixels PX. The thickness T1 of the first conductivity-type semiconductor base layer 111B may be, for example, about 0.1 μm or greater. In some example embodiments, the thickness T1 of the first conductivity-type semiconductor base layer 111B may be in the range of about 0.1 μm to about 1.0 μm. The first conductivity-type semiconductor base layer 111B may be disposed to extend from the display area DA to a connection region CR and the pad regions PAD, that is, a portion of the peripheral area PA. The first conductivity-type semiconductor base layer 111B may be provided as a region for forming a common electrode for the entirety or a portion (e.g., the same row or column) of first to third LED cells LC1, LC2, and LC3.

Referring to FIGS. 3 and 4A, the passivation layer 120 may cover the side surface and upper surface of the first to third LED cells LC1, LC2, and LC3 and the first surface of the first conductivity-type semiconductor base layer 111B. The passivation layer 120 may extend to the peripheral area PA on the first surface of the first conductivity-type semiconductor base layer 111B. The passivation layer 120 may be disposed to cover the lower surface of the first conductivity-type semiconductor layer 112 in the connection region CR and the pad regions PAD, that is, the peripheral area PA. The passivation layer 120 may include at least one of an insulating material, for example, at least one of SiO₂, SiN, SiCN, SiOC, SiON and SiOCN.

The first electrode 130 may be connected to the first conductivity-type semiconductor base layer 111B. Specifically, the first electrode 130 may be disposed to be electrically insulated from the first to third LED cells LC1, LC2, and LC3 by the passivation layer 120. The first electrode 130 may extend to the peripheral area PA. The first electrode 130 extending to the peripheral area PA may be connected in regions between adjacent first to third LED cells LC1, LC2, and LC3 and may be disposed in a single layer. The first electrode 130 may include a reflective metal material. For example, the first electrode 130 may include at least one of silver (Ag), nickel (Ni), aluminum (Al), chromium (CR), rhodium (Rh), iridium (Ir), palladium (Pd), ruthenium (Ru), magnesium (Mg), zinc (Zn), platinum (Pt), gold (Au), copper (Cu), titanium (Ti), tantalum (Ta), and tungsten (W). In some example embodiments, the first electrode 130 may include a compound such as TaN or TiN or a transparent electrode material such as ITO, IZO, or GAZO. In some example embodiments, the first electrode 130 may include a single layer structure or a multiple layer structure formed of a conductive material.

The first electrode 130 may be provided as a reflective electrode (also referred to as “first reflective electrode”). For example, as shown in FIG. 3, the first electrode 130 may have a cross-sectional surface of an inverted-U shape between adjacent LED cells LC1, LC2, and LC3. The first electrode 130 may have a grid or mesh shape including lines extending in the X and Y directions along regions between the pixels PX and the first to third sub-pixels SP1, SP2, and SP3. Ends of the first electrode 130 may be connected to the common electrode 145. As illustrated in FIG. 3, the outermost portions of the first electrode 130 may be connected to the common electrode 145.

In some example embodiments, the first electrode 130 may extend to a peripheral area PA, that is, a connection region CR disposed on an outer region of the pixels PX, may be connected to the first conductivity-type semiconductor base layer 111B), and may be physically and electrically connected to the common electrode 145. As in some example embodiments, the first electrode 130 may be electrically connected to the first conductivity-type semiconductor base layer 111B in a region between adjacent LED cells LC1, LC2, and LC3.

The contact layers 155 and the second electrodes 150 may be disposed in order on lower surfaces of the second conductivity-type semiconductor layers 116 and may be connected to the second conductivity-type semiconductor layers 116. In some example embodiments, the contact layers 155 may be disposed to cover almost the entire lower surface of the second conductivity-type semiconductor layer 116. Similarly to the first electrode 130, the second electrodes 150 may include a reflective metal material. For example, the second electrode 150 may include at least one of silver (Ag), nickel (Ni), aluminum (Al), chromium (CR), rhodium (Rh), iridium (Ir), palladium (Pd), ruthenium (Ru), magnesium (Mg), zinc (Zn), platinum (Pt), and gold (Au), copper (Cu), titanium (Ti), tantalum (Ta), and tungsten (W). In some example embodiments, the second electrode 150 may include a compound such as TaN or TiN or a transparent electrode material such as ITO, IZO, or GAZO. In some example embodiments, the second electrode 150 may include a single layer structure or a multiple layer structure formed of a conductive material.

The second electrode 150 (also referred to as “second reflective electrode”), which is a reflective electrode, may be disposed below each LED cell 110 to overlap the LED cells 110 in the Z direction. The second electrode 150 may be disposed below the contact layer 155 and may be connected to the contact layer 155. The length of the second electrode 150 in the X direction may be the same as or similar to the length of the LED cells LC1, LC2, and LC3, but some example embodiments thereof is not limited thereto and may be varied In some example embodiments. In some example embodiments, the second electrodes 150 may not be provided, and in the case, the contact layers 155 may be directly connected to the first bonding electrodes 198 therebelow.

The contact layers 155 and second electrodes 150 may include, for example, a highly reflective metal, such as at least one of silver (Ag), nickel (Ni), aluminum (Al), chromium CR), rhodium (Rh), iridium (Ir), palladium (Pd), ruthenium (Ru), magnesium (Mg), zinc (Zn), platinum (Pt), and gold (Au).

The pixel array 100 in some example embodiments may further include a planarization layer 182, a first pad electrode 147, a first wiring insulating layer 195, a first bonding insulating layer 190, first bonding electrodes 198, and a second pad electrode 199 on a partition structure 111P and a semiconductor layer 111 filled with a transparent resin portion 160.

As described above, the semiconductor layer 111 may include a region integrated with or continuous from the first conductivity-type semiconductor layer 111B. As illustrated in FIG. 3, the semiconductor layer 111 in the peripheral area PA may have a layer structure other than the partition structure 111P, and the common electrode 145 may extend to the semiconductor layer 111 region of the peripheral area PA. A through hole OP in which a portion of the semiconductor layer 111 is removed may be formed in the peripheral area PA, in particular, the pad regions PAD.

The planarization layer 182 may be a transparent layer formed on the partition structure 111P and the semiconductor layer 111 filled with the transparent resin portion 160. The microlenses 185 may be disposed to correspond to the first to third sub-pixels SP1, SP2, and SP3 on the planarization layer 182, and may collect light emitted from the first to third LED cells LC1, LC2, and LC3. The microlenses 185 may have a larger diameter than the widths of the LED cells LC1, LC2, and LC3 in the X and Y directions, for example. The microlenses 185 may be formed of, for example, a transparent photoresist material or may be formed with a transparent thermosetting resin film.

The common electrode 145 and the first pad electrode 147 may be disposed in the connection regions CR and the pad regions PAD, respectively. The common electrode 145 may be disposed on the lower surface of the first reflective electrode 130 extending from the pixel PX and may connect the first reflective electrode 130 to the first bonding electrode 198. The common electrode 145 may form a common electrode structure together with the first reflective electrode 130. The common electrode 145 may be disposed in a square ring shape or a ring shape to enclose the entire pixels PX in a plan diagram, and may be connected to ends of the first reflective electrode 130. However, the arrangement form of the common electrode 145 is not limited thereto, and in some example embodiments may be varied. The first pad electrode 147 may be disposed below the second pad electrode 199 in the pad regions PAD and may connect the second pad electrode 199 to the first bonding electrode 198. The common electrode 145 and first pad electrode 147 may include a conductive material such as, for example, at least one of silver (Ag), nickel (Ni), aluminum (Al), chromium CR, rhodium (Rh), iridium (Ir), palladium (Pd), ruthenium (Ru), magnesium (Mg), zinc (Zn), platinum (Pt), and gold (Au).

The first bonding electrodes 198 may connect the second reflective electrodes 150, the common electrode 145, and the first pad electrode 147 to the second bonding electrodes 298 of the circuit board 200. The first bonding electrodes 198 may be connected to the second electrodes 150 below the second electrodes 150 in the pixel PX, may be connected to the common electrode 145 in the connection region CR, and may be connected to the first pad electrode 147 in the pad regions PAD. In some example embodiments, among the first bonding electrodes 198, the bonding electrodes disposed on the common electrode 145 and the first pad electrode 147 may be referred to as “a third bonding electrode” and “a fourth bonding electrode” respectively. The first electrode 130 may be connected to the first bonding electrodes 198 through the common electrode 145, and the second electrodes 150 may be directly connected to the first bonding electrodes 198.

The first bonding electrodes 198 may be disposed to penetrate through the first wiring insulating layer 195 and the second bonding insulating layer 290. The first bonding electrodes 198 may have a columnar shape such as a cylinder. In some example embodiments, the first bonding electrodes 198 may have inclined sidewalls such that an upper surface size may be smaller than a size of a lower surface thereof. The first bonding electrodes 198 may include, for example, copper (Cu). The first bonding electrodes 198 may further include a barrier metal layer, for example, a tantalum (Ta) layer and/or a tantalum nitride (TaN) layer, on upper and side surfaces thereof.

The first wiring insulating layer 195 may be disposed below the LED cells LC1, LC2, and LC3 and the semiconductor layer 111 together with the second bonding insulating layer 290. For example, the first wiring insulating layer 195 may include at least one of SiO₂, SiN, SiCN, and SiON. In some example embodiments, the first wiring insulating layer 195 may be tetraethyl ortho silicate (TEOS), undoped silicate glass (USG), phosphosilicate glass (PSG), borosilicate glass (BSG), borophosphosilicate glass (BPSG), fluoride silicate glass (FSG), spin on glass (SOG), tonen silazene (TOSZ), or a combination thereof.

The semiconductor substrate 201 may include impurity regions including source/drain regions 205. The semiconductor substrate 201 may include, for example, a semiconductor such as silicon (Si) or germanium (Ge) or a compound semiconductor such as SiGe, SiC, GaAs, InAs, or InP. The semiconductor substrate 201 may further include through electrodes 250 such as through silicon via (TSV) connected to the driver circuit, and first substrate wiring lines 261 and second substrate wiring lines 262 connected through electrodes 250.

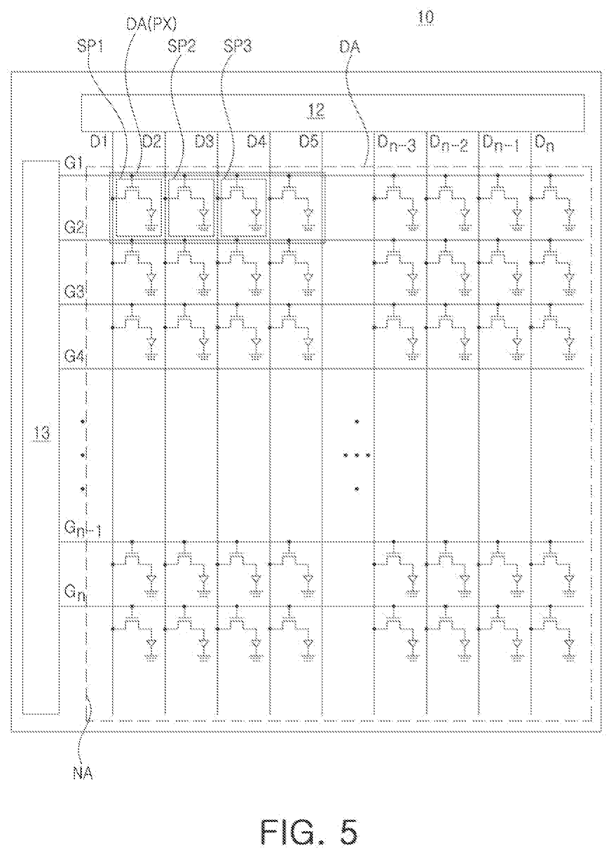

The driver circuit may include a circuit for controlling driving of a pixel, particularly a sub-pixel. The source region 205 of the TFT cells may be electrically connected to an electrode on one side of the LED cells 110 through an interconnection portion 230, a wiring layer 240, and a first bonding electrode 298. For example, the drain region 205 of the TFT cells may be connected to a first wiring line 261 through a through electrode 250, and the first wiring line 261 may be connected to a data line. Gate electrodes of the TFT cells may be connected to a second wiring line 262 through a through electrode 250, and the second wiring line 262 may be connected to the gate line. The circuit configuration and operation will be described in greater detail with reference to FIG. 5 below.

The upper surfaces of the second bonding electrodes 298 and the upper surfaces of the second bonding insulating layer 290 may form the upper surface of the circuit board 200. The second bonding electrodes 298 may be bonded to the first bonding electrodes 198 of the pixel array 100 and may provide an electrical connection path. The second bonding electrodes 298 may include a conductive material, for example, copper (Cu). The second bonding insulating layer 295 may be bonded to the first bonding insulating layer 190 of the pixel array 100. For example, the second bonding insulating layer 295 may include at least one of SiO, SiN, SiCN, SiOC, SiON, and SiOCN.

Lower surfaces of the second bonding insulating layer 290 may be arranged to form a lower surface of the pixel array 100 together with lower surfaces of the second bonding electrodes 198. The second bonding insulating layer 290 may form dielectric-dielectric bonding with the first bonding insulating layer 190. The circuit board 200 and the pixel array 100 may be bonded by bonding between the first bonding electrodes 198 and second bonding electrodes 298 and bonding between the first bonding insulating layer 190 and the second bonding insulating layer 290. The bonding between the first bonding electrodes 198 and the second bonding electrodes 298 may be, for example, copper (Cu)-copper (Cu) bonding, and bonding between the first bonding insulating layer 190 and the second bonding insulating layer 290 may be, for example, dielectric-dielectric bonding such as SiCN—SiCN bonding. The circuit board 200 and the pixel array 100 may be bonded to each other by hybrid bonding including copper (Cu)-copper (Cu) bonding and dielectric-dielectric bonding, and may be bonded without an adhesive layer.

In the display apparatus 10 according to some example embodiments, the arrangement of electrode structures including the first electrode 130 may be optimized and the circuit board 200 and the pixel array 100 may be bonded to each other using hybrid bonding, thereby, implementing a miniaturized high-resolution device.

The second pad electrode 199 may be disposed on the first pad electrode 147 in pad regions PAD. The second pad electrode 199 may be disposed such that at least an upper surface may be upwardly exposed by a through structure OP penetrating the semiconductor layer 111 and the first conductivity-type semiconductor layer 112. The second pad electrode 199 may be connected to an external device, for example, an external circuit (external IC) for applying an electrical signal to the circuit board 200 by wire bonding or anisotropic conductive film (AFC) bonding. The second pad electrode 199 may electrically connect driver circuits of the circuit board 200 to the external device. The second pad electrode 199 may include metal, such as gold (Au), silver (Ag), or nickel (Ni).

FIG. 5 is a diagram illustrating a driver circuit implemented in a display apparatus according to some example embodiments.

FIG. 5 illustrates a circuit diagram of a display apparatus 10 in which n×n sub-pixels are arranged. The first to third sub-pixels SP1, SP2, and SP3 may receive data signals through data lines D1-Dn, which are vertical paths, for example, in a column direction. The first to third sub-pixels SP1, SP2, and SP3 may receive control signals, that is, gate signals, through gate lines G1-Gn which may be horizontal, for example, row-direction paths.

A plurality of pixels PX including first to third sub-pixels SP1, SP2, and SP3 may provide a display area DA, and the display area DA may be provided as a display area for a user as an active region. The inactive region NA (or peripheral area PA) may be formed along one or more edges of the display area DA. The inactive region NA may extend along the outer circumference of the panel of the display apparatus 10.

A first driver circuit 12 and a second driver circuit 13 may be employed to control the operation of pixels PX, that is, first to third sub-pixels SP1, SP2, and SP3. A portion or the entirety of the first and second driver circuits 12 and 13 may be implemented on the circuit board 200. The first and second driver circuits 12 and 13 may be formed as integrated circuits, thin film transistor panel circuits, or other suitable circuits, and may be disposed in the inactive region NA of the display apparatus 10. The first and second driver circuits 12 and 13 may include a microprocessor, a memory such as a storage, a processing circuitry, and a communication circuitry.

To display an image by pixels PX, the first driver circuit 12 may supply image data to data lines D1-Dn, and may send a clock signal and other control signals to the second driver circuit 13, which is a gate driver circuit. The second driver circuit 13 may be implemented using an integrated circuit and/or a thin film transistor circuit. A gate signal for controlling first to third sub-pixels SP1, SP2, and SP3 arranged in a row direction may be transmitted through gate lines G1-Gn of the display apparatus 10.

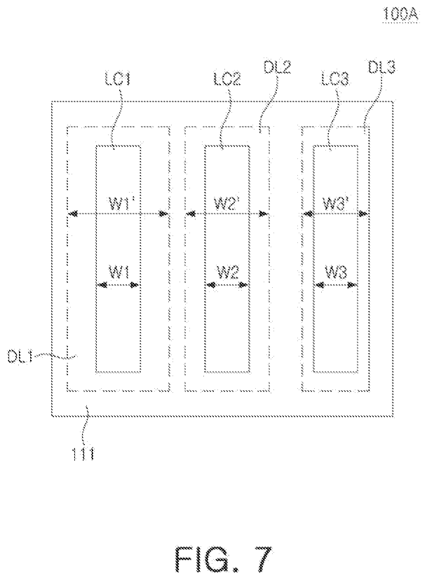

FIGS. 6A to 6E are cross-sectional diagrams illustrating processes of a method of manufacturing an LED module according to some example embodiments. FIG. 7 is a plan diagram illustrating the LED module illustrated in FIG. 6E.

The method of manufacturing an LED module according to some example embodiments may be understood as a process of manufacturing an LED module (see FIGS. 4A and 4B) corresponding to a pixel in a pixel array of a display.

Referring to FIG. 6A, an under-semiconductor layer 111 may be formed on a growth substrate 101, and a mask pattern 105 may be formed on the under-semiconductor layer 111.

An upper region of the under-semiconductor layer 111 in some example embodiments may include a first conductivity-type semiconductor base layer 111B. In some example embodiments, the lower region of the under-semiconductor layer 111 may be a first conductivity-type semiconductor layer or an undoped semiconductor layer, or may include a laminate of a first conductivity-type semiconductor layer and an undoped semiconductor layer.

The mask pattern 105 may have a first opening O1, a second opening O2, and a third opening O3 for opening regions of the first conductivity-type semiconductor base layer 111B. Regions of the first conductivity-type semiconductor base layer 111B may be provided as regions for forming first to third LED cells, respectively. The first opening O1, the second opening O2 and the third opening O3 may be arranged with the same pitch (P1=P2). Here, each pitch P1 and P2 may be defined as a distance between centers of openings adjacent to each other.

In some example embodiments, the first to third openings O1, O2, and O3 may have different widths W1′, W2′, and W3′. Specifically, the width W′1 of the first opening O1 may be greater than the width W2′ of the second opening O2, and the width W2′ of the second opening O2 may be greater than the width W3′ of the third opening O3. Depending on the conditions of the same pitch and different widths, the pattern distances d1, d2, and d3, respectively, of the openings O1, O2, and O3 may be different (i.e., (d1≠d2≠d3)).

Since the area of the grown region provided by the first to third openings O1, O2, and O3 is different as described above, even when the active layers (i.e., even when the quantum well layer) are grown simultaneously in the first to third openings O1, O2, and O3, active layers emitting light of different wavelengths may be formed.

Thereafter, referring to FIG. 6B, a first conductivity-type semiconductor cap layer 112 may be formed on regions of the first conductivity-type semiconductor base layer 111B opened by first to third openings O1, O2, and O3.

The first conductivity-type semiconductor cap layer 112 may be a nitride single crystal having a composition of n-type InₓAl_{y}Ga_{1-x-y}N(0≤x<1, 0≤y<1, 0≤x+y<1) similar to that of the first conductivity-type semiconductor base layer 111B. For example, the first conductivity-type semiconductor base layer 111B and the first conductivity-type semiconductor cap layer 112 may be n-type gallium nitride (n-GaN) layers doped with silicon (Si), germanium (Ge), or carbon (C). In some example embodiments, the process may not be performed, but may be added to grow active layers to be grown in subsequent processes on high-quality crystal planes. In some example embodiments, the first conductivity-type semiconductor cap layer 112 may be grown as a nitride single crystal having a c-plane, that is, a (0001) plane, having an upper surface, and an edge region adjacent to the mask pattern 105 may have an inclined side surface.

Thereafter, referring to FIG. 6C, active layers 114a, 114b, and 114c may be formed on the first conductivity-type semiconductor cap layer 112, respectively, and second conductivity-type semiconductor layers 116 may be grown on the active layers 114a, 114b, and 114c, respectively.

The growth processes in the opening O1, O2, and O3 may be performed simultaneously using a single growth process. Through this process, first to third light emitting laminates LC1′, LC2′, and LC3′ may be formed in the first to third openings O1, O2, and O3, respectively. For example, the first light emitting laminate LC1′ may include the first conductivity-type semiconductor cap layer 112, the first active layer 114a, and the second conductivity-type semiconductor layer 116, and the second light emitting laminate LC2′ may include the first conductivity-type semiconductor cap layer 112, the second active layer 114b, and the second conductivity-type semiconductor layer 116, and the third light emitting laminate LC3′ may include the first conductivity-type semiconductor cap layer 112, the third active layer 114c, and the second conductivity-type semiconductor layer 116.

As described above, even when the components are grown by the same process, due to the difference in area sizes of the openings O1, O2, and O3, the first to third light emitting laminates LC1′, LC2′, and LC3′ may have first to third active layers 114a, 114b, and 114c configured to emit light of different wavelengths. The first active layer 114a may include a first quantum well layer configured to emit blue light, for example, light having a wavelength of 440 nm to 480 nm. The second active layer 114b may include a second quantum well layer configured to emit green light, for example, light having a wavelength of 510 nm to 550 nm. Also, the third active layer 114c may include a third quantum well layer configured to emit red light, for example, light having a wavelength of 610 nm to 650 nm.

Specifically, the first to third active layers 114a, 114b, and 114c may have first to third quantum well layers represented as InₓGa₁₋ₓN(0<x≤1). The first to third quantum well layers may have different contents of indium (x). For example, the content of indium of the first quantum well layer may be in the range of 0.15-0.2, the content of indium of the second quantum well layer may be in the range of 0.25-0.3, and the content of indium of the third quantum well layer may be in the range of 0.3-0.35.

In some example embodiments, the thickness of the first quantum well layer may be greater than the thickness of the second quantum well layer, and the thickness of the second quantum well layer may be greater than the thickness of the third quantum well layer. Specifically, the thickness t1 of the first active layer 114a may be greater than the thickness t2 of the second active layer 114b, and the thickness t2 of the second active layer 114b may be greater than the thickness t3 of the third active layer 114c.

The first to third quantum well layers may be simultaneously formed in the same growth process as described above, but by controlling the area sizes of the grown region for the first to third LED cells LC1, LC2, and LC3, the difference in content of indium may be induced, and accordingly, the first to third light emitting laminates LC1′, LC2′, and LC3′ may be configured to emit light of different wavelengths.

The first to third active layers 114a, 114b, and 114c may have a single quantum well (SQW) structure, or a multiple quantum well (MQW) structure in which quantum barrier layers and quantum well layers are alternately arranged. For example, the quantum barrier layer may be GaN or AlGaN. Since the first to third active layers 114a, 114b, and 114c are simultaneously formed by the same growth process, the active layers may include layers corresponding to each other. The first to third active layers 114a, 114b, and 114c may include the same number of quantum barrier layers and quantum well layers.

Thereafter, second conductivity-type semiconductor layers 116 may be simultaneously formed on the first to third active layers 114a, 114b, and 114c, respectively. The second conductivity-type semiconductor layer 116 may be a nitride semiconductor layer having a composition of p-type InₓAl_{y}Ga_{1-x-y}N(0≤x<1, 0≤y<1, 0≤x+y<1). For example, the second conductivity-type semiconductor layer 116 may be a p-type gallium nitride (p-GaN) layer doped with magnesium (Mg) or zinc (Zn).

Thereafter, referring to FIG. 6D, the mask pattern 105 may be removed from the first conductivity-type semiconductor base layer 111B.

After removing the mask pattern 105, first to third light emitting laminates LC1′, LC2′, and LC3′ may remain on the first conductivity-type semiconductor base layer 111B. As described above, the first to third light emitting laminates LC1′, LC2′, and LC3′ may include a nitride single crystal having an upper surface, which is the (0001) plane, and may include edge regions DL1, DL2, and DL3 having inclined side surfaces. The edge regions DL1, DL2, and DL3 may be crystal damaged regions generating non-radiative recombination or leakage current. Accordingly, a process of removing the edge regions may be performed. In some example embodiments, the shape and size (or width) of the first to third light emitting laminates LC1′, LC2′, and LC3′ remaining in the edge region removal process may be controlled.

The widths of the edge regions DL1, DL2, and DL3 to be removed may be determined differently such that the remaining first to third light emitting laminates LC1, LC2, and LC3 may have the same width (i.e., W1=W2=W3). The edge region removal process may be performed by dry etching, wet etching, or a combination of dry/wet etching. As illustrated in FIG. 7, on a plane, edge regions DL1, DL2, and DL3 to be removed may be disposed to surround the first to third light emitting laminates LC1, LC2, and LC3, respectively.

Thereafter, referring to FIG. 6E, after removing the edge regions DL1, DL2, and DL3, first to third light emitting laminates LC1, LC2, and LC3 having the same width (i.e., W1=W2=W3) may be obtained.

In some example embodiments, the remaining first to third light emitting laminates may also be referred to as first to third LED cells LC1, LC2, and LC3, respectively. The first to third LED cells LC1, LC2, and LC3 may be provided as light sources for first to third sub-pixels, respectively. The first to third LED cells LC1, LC2, and LC3 may be maintained with the same pitch (P1=P2) therebetween. In some example embodiments, the first to third LED cells LC1, LC2, and LC3 may be separated from each other by different distances (d1>d2).

As described above, the first to third LED cells LC1, LC2, and LC3 may have an upper surface, which is a (0001) plane, and a side surface almost perpendicular to the upper surface of the first conductivity-type semiconductor base layer 111B. For example, the side surface angle of first to third LED cells LC1, LC2, and LC3 with respect to the growth substrate 101 may be in the range of 85°-95°.

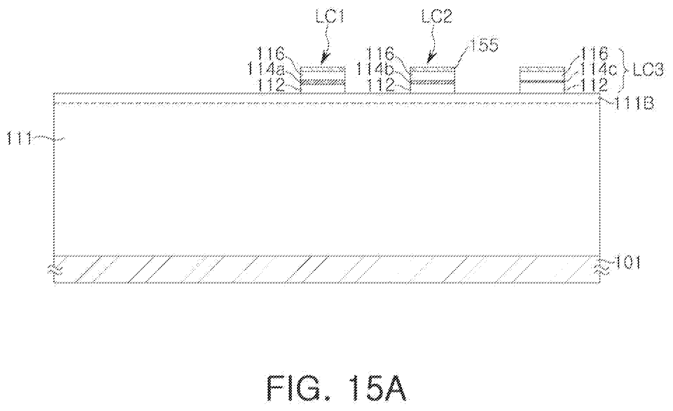

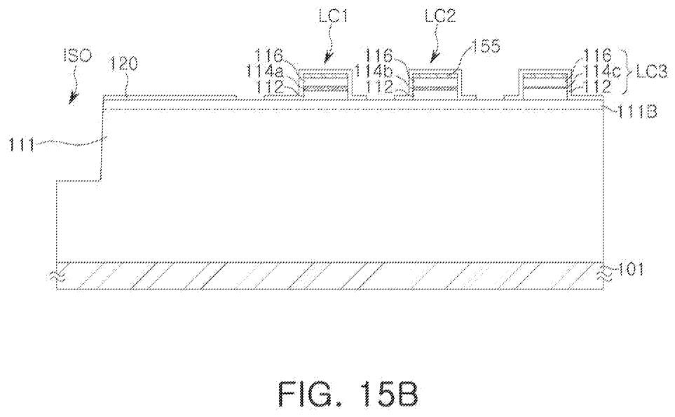

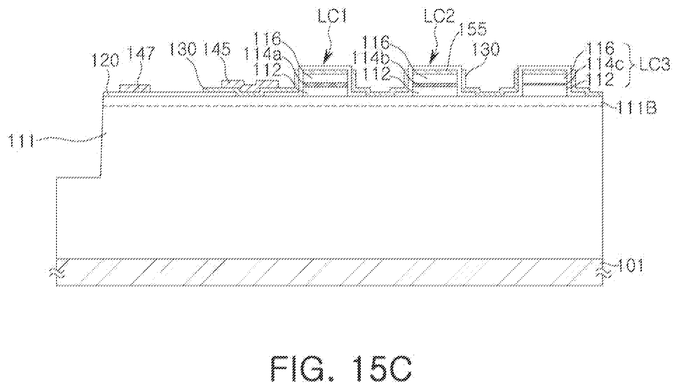

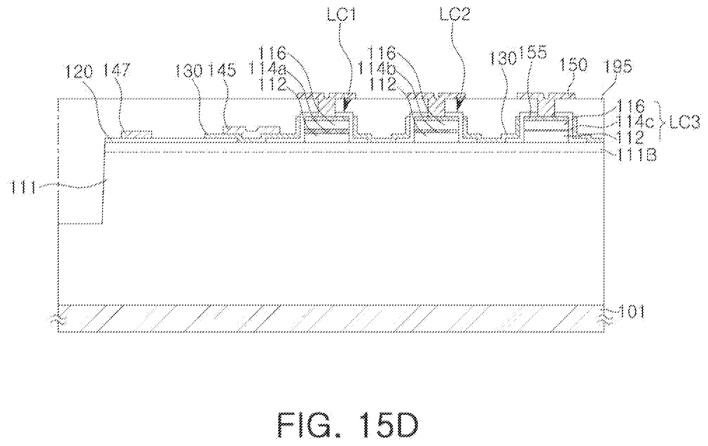

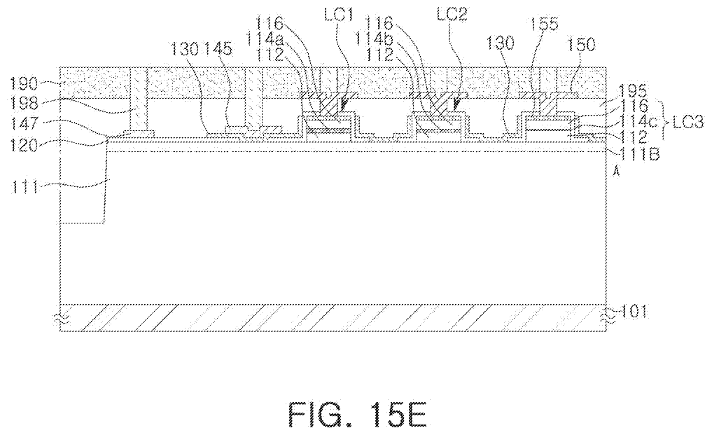

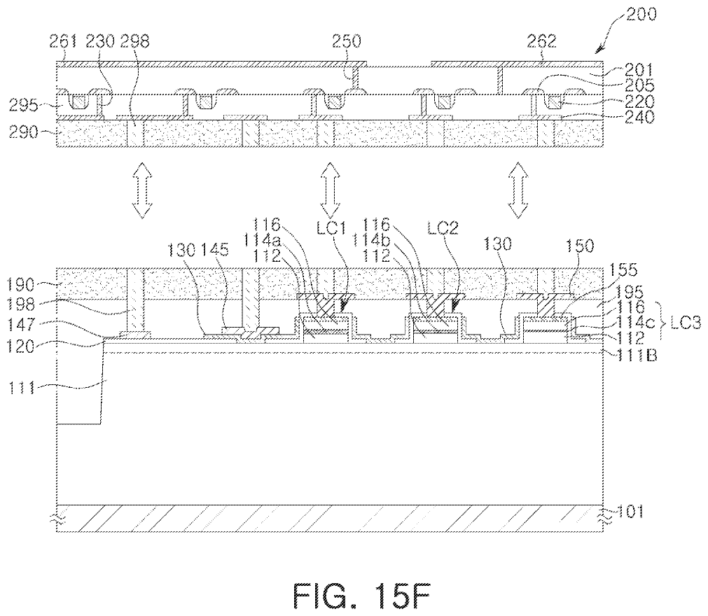

Thereafter, the LED module (100A) illustrated in FIG. 6E may be additionally processed to be manufactured as a pixel array substrate (see “100” in FIG. 3) for display. A pixel array substrate manufacturing process may be performed by the processes in FIGS. 15A to 15E.

For example, the passivation layer 120 may be formed on the upper surface of the first conductivity-type semiconductor base layer 111B and the side surface and upper surface of the first to third LED cells LC1, LC2, and LC3. Thereafter, first electrodes 155, which are individual electrodes, may be formed on the upper surface of the first to third LED cells LC1, LC2, and LC3 to be connected to the second conductivity-type semiconductor layers 116, and a second electrode 130, a common electrode, connected to the first conductivity-type semiconductor base layer 111B may be formed.

In the process of removing the edge region of the light emitting laminate, the shape and size of LED cells may be controlled in various manners. In some example embodiments, the sizes (or widths) of first to third LED cells may be determined to be different. Some example embodiments will be described with reference to FIGS. 8A, 8B and 9.

FIGS. 8A and 8B are cross-sectional diagrams illustrating processes of a method of manufacturing an LED module according to some example embodiments. FIG. 9 is a plan diagram illustrating the LED module illustrated in FIG. 8B.

FIG. 8A illustrates first to third light emitting laminates LC1′, LC2′, and LC3′ disposed on the under-semiconductor layer 111. The first to third light emitting laminates LC1′, LC2′, and LC3′ may be understood as results obtained after performing the processes in FIGS. 6A and 6B in the aforementioned example embodiment.

As described above, the first to third light emitting laminates LC1′, LC2′, and LC3′ may include a nitride single crystal having an upper surface, a (0001) plane, and an edge region DL having an inclined side surface. In some example embodiments, after removing the edge region DL, first to third light emitting laminates, that is, first to third LED cells LC1, LC2, and LC3 may have different widths (Wa>Wb>Wc). For example, considering efficiency according to the wavelength of light, the width (or area) of the LED cell having relatively low efficiency may be configured to be large.

In some example embodiments, the width Wa of the first LED cell LC1 for blue light may be greater than the width Wb of the second LED cell LC2 for green light, and the width Wb of the second LED cell LC2 may be greater than the width We of the third LED cell LC3 for red light. The distance (da=db) of LED cells adjacent to each other may be the same or different, but the first to third LED cells LC1, LC2, and LC3 may be arranged with the same pitch (P1=P2) therebetween.

In some example embodiments, as illustrated in FIG. 9, on a plane, the edge region DL surrounding each of the first to third LED cells LC1, LC2, and LC3 may be removed with a sufficient width Wd for the damaged region to be removed. In some example embodiments, the widths Wd of the edge regions DL removed from the first to third LED cells LC1, LC2, and LC3 may be substantially the same.

As such, the LED module 100B manufactured in some example embodiments may include the first to third LED cells LC1, LC2, and LC3 with different widths (Wa≠Wb≠Wc) and different distances (da≠db) but arranged with the same pitch (P1=P2).

The LED modules 100A and 100B corresponding to a pixel may include the first to third LED cells arranged in one direction, but may be varied depending on the arrangement of sub-pixels. For example, the LED module 100C illustrated in FIG. 10 may include four LED cells LC1, LC2a, LC2b, and LC3 arranged with the same pitch (Pa=Pb=Pc) similarly to the Bayer pattern (R-G-G-B), and the four LED cells may include blue LED cell L1 and red LED cell L3 arranged in a first diagonal line, and first green LED cell LC2a and second green LED cell LC2b arranged in a second diagonal line. In FIG. 10, dotted lines may represent outer lines of the light emitting laminates before the opening or edge regions DL1, DL2, and DL3 of the mask pattern are removed. The four LED cells LC1, LC2a, LC2b, and LC3 may be formed in openings having different widths. In some example embodiments, four LED cells LC1, LC2a, LC2b, and LC3 may have the same size (W1=W2=W3) after removing the edge region. However, some example embodiments thereof is not limited thereto, and as described in FIG. 9, by adjusting the width of the edge region DL1, DL2, and DL3 to be removed, the LED cells may have different sizes depending on the wavelength of each LED cell LC1, LC2a, LC2b, and LC3.

In the above-described example embodiments, an example is described in which the first to third LED cells emitting different wavelengths of light, for example, blue, green and red LED cells may be formed simultaneously, but example embodiments are not limited to this and, in some example embodiments may be varied.

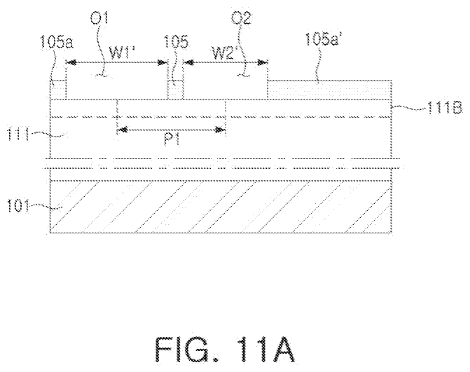

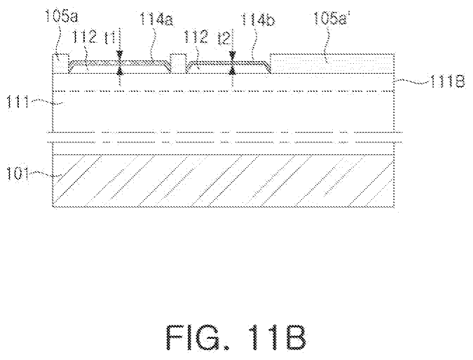

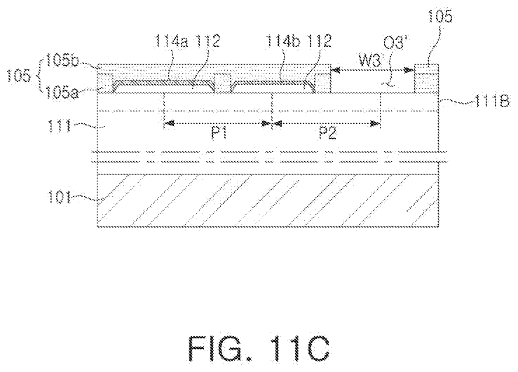

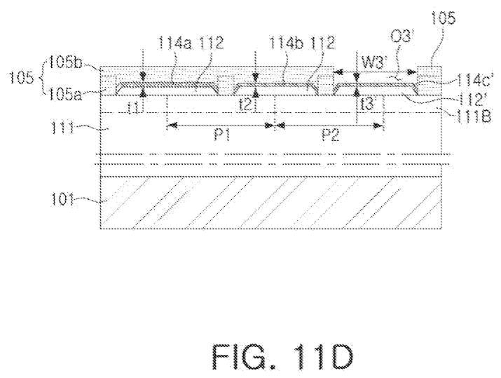

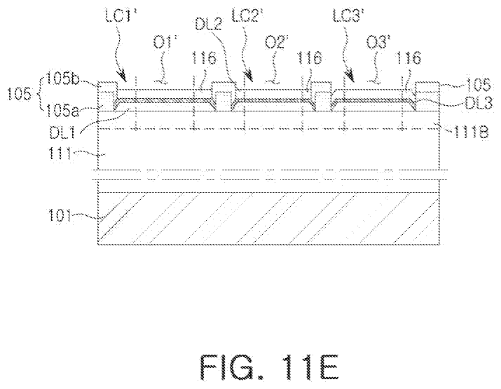

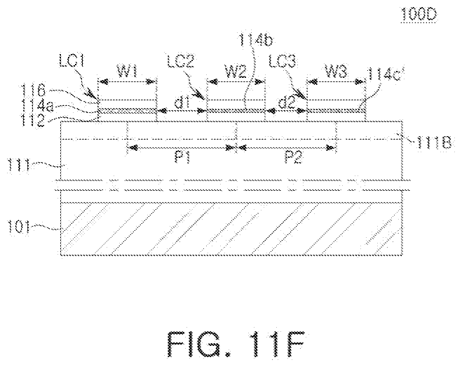

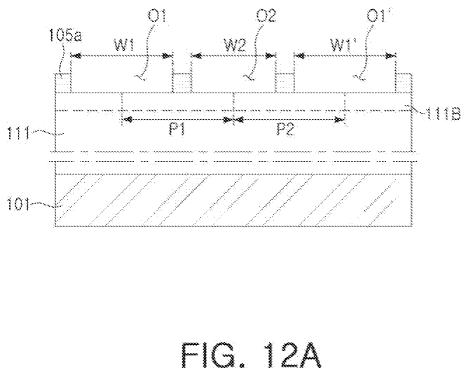

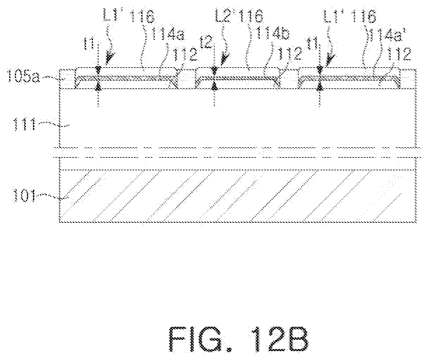

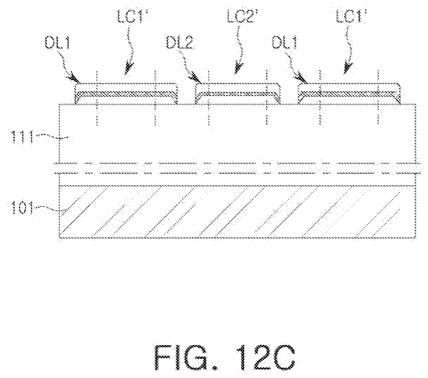

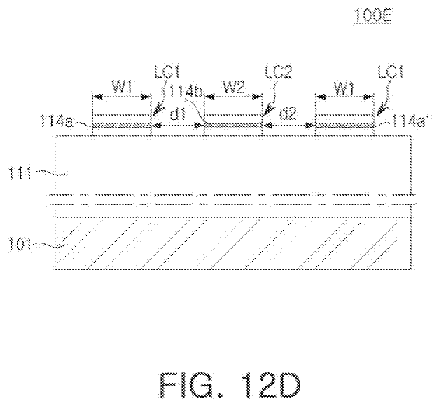

According to some example embodiments, in a pixel unit, only first and second LED cells emitting light of different colors may be formed simultaneously, and third LED cells emitting light of other colors may be formed in a different process (see FIGS. 11A to 11F). According to some example embodiments, in a pixel unit, two LED cells emitting light of one color (e.g., blue) and an LED cell emitting light of another color (e.g., green) may be simultaneously formed, and a wavelength converter may be applied to one of the two LED cells (see FIGS. 12A to 12D).

FIGS. 11A to 11F are cross-sectional diagrams illustrating a portion of processes of a method of manufacturing a display apparatus according to some example embodiments.

Referring to FIG. 11A, an under-semiconductor layer 111 having a first conductivity-type semiconductor base layer 111B may be formed on a growth substrate 101, and a first mask pattern 105a may be formed on the first conductivity-type semiconductor base layer 111B.

The first mask pattern 105a may have a first opening O1 and a second opening O2 having different widths (i.e., W1′#W2′), and the first opening O1 and second opening O2 may be arranged with a first pitch P1. Here, the width W1′ of the first opening O1 may be greater than the width W2′ of the second opening O2. For example, a deviation of the widths W1′ and W2′ of the first and second openings O1 and O2 may be determined such that active layers for blue and green may be formed in the first and second openings O1 and O2, respectively, in the same process. The first mask pattern 105a may have a portion 105a′ covering a region for forming a third LED cell in a subsequent process.

Thereafter, referring to FIG. 11B, the first conductivity-type semiconductor cap layer 112 and the first and second active layers 114a and 114b may be grown simultaneously in regions of the first conductivity-type semiconductor base layer 111B opened by the first and second openings O1 and O2.

The first and second active layers 114a and 114b may include first and second quantum well layers emitting first light (e.g., blue) and second light (green) of different wavelengths, respectively. The content of indium of the first quantum well layer may be in the range of 0.15-0.2, and the content of indium of the second quantum well layer may be in the range of 0.25-0.3. The first quantum well layer may emit light having a wavelength of 440 nm-480 nm, and the second quantum well layer may emit light having a wavelength of 510 nm-550 nm. In some example embodiments, the thickness t1 of the first active layer 114a may be greater than the thickness t2 of the second active layer 114b.

Thereafter, referring to FIG. 11C, a second mask pattern 105b covering the first and second openings O1 and O2 may be formed. The second mask pattern 105b may have having a third opening O3′ such that an opening in another region of the first conductivity-type semiconductor base layer 111B may be formed.

In this process, a process of forming a dielectric layer for the second mask pattern 105b to cover the first and second openings O1 and O2 and opening the third opening O3′ may be performed.

The third opening O3′ may be arranged with the second pitch P2 with an adjacent opening, that is, the second opening O2, among the first and second openings, and the second pitch P2 may be the same as the first pitch P1. The width W3 of the third opening O3 may be arbitrarily determined. For ease of process, the width W3 of the third opening O3 may be substantially the same as the width W1 or W2 of the first or second openings O1 and O2.

Thereafter, referring to FIG. 11D, a first conductivity-type semiconductor cap layer 112′ and a third active layer 114c′ may be formed in another region of the first conductivity-type semiconductor base layer 111B opened by the third opening O3′.

The first conductivity-type semiconductor cap layer 112′ of the third opening O3′ may be the same nitride layer as the first conductivity-type semiconductor cap layer 112 of the other openings O1 and O2. The third active layer 114c′ may include a third quantum well layer configured to emit third light (e.g., red) of a wavelength different from that of the first and second lights. The third quantum well layer may emit light having a wavelength of 610 nm to 650 nm.

As such, in some example embodiments, the third active layer 114c′ may be formed by a growth process different from the process of forming the first and second active layers 114a and 114b. In some example embodiments, the first and second active layers 114a and 114b may be formed simultaneously, such that the active layers may have different corresponding layer structures (the same number of quantum bather layers and quantum well layers), and the third active layer 114c′ may have a layer structure different from that of the first and second active layers 114a and 114b.

Thereafter, referring to FIG. 11E, fourth and fifth openings O1′ and O2′ for opening the first and second active layers 114a and 114b, respectively, may be formed in the second mask pattern 105b, and second conductivity-type semiconductor layers 116 may be grown on the first to third active layers 114a, 114b, and 114c, respectively. Accordingly, first to third light emitting laminates LC1′, LC2′, and LC3′ arranged with the same pitch (P1=P2) may be formed.

Thereafter, referring to FIG. 11F, the first and second mask patterns 105a and 105b may be removed from the first conductivity-type semiconductor base layer 111B, and edge regions of the first to third light emitting laminates LC1′, LC2′, and LC3′ may be removed.

After removing the entire mask pattern 105, first to third light emitting laminates LC1′, LC2′, and LC3′ may remain on the first conductivity-type semiconductor base layer 111B. As described above, the first to third light emitting laminates LC1′, LC2′, and LC3′ may include damaged edge regions. In some example embodiments, first to third light emitting laminates LC1, LC2, and LC3 having the same width (i.e., W1=W2=W3) may be obtained after removing the edge regions DL1, DL2, and DL3. The LED cells LC1, LC2, and LC3 may be provided as light sources for first to third sub-pixels, respectively. The first to third LED cells LC1, LC2, and LC3 may be maintained with the same pitch (P1=P2).

FIGS. 12A to 12D are cross-sectional diagrams illustrating a portion of processes of a method of manufacturing a display apparatus according to some example embodiments.

Referring to FIG. 12A, an under-semiconductor layer 111 having a first conductivity-type semiconductor base layer 111B may be formed on a growth substrate 101, and a mask pattern having first to third openings O1, O2, and O1′ may be formed on the first conductivity-type semiconductor base layer 111B.

The first to third openings O1, O2, and O1′ may be arranged with the same pitch (P1=P2), and the width W1 of the first opening O1 may be greater than the width (W2) of the second opening O2 and may be equal to the width W1′ of the third opening O1′.

Thereafter, referring to FIG. 12B, a first conductivity-type semiconductor cap layer 112, first to third active layers 114a, 114b, and 114a′ and second conductivity-type semiconductor layers 116 may be grown in each of the regions of the first conductivity-type semiconductor base layer 111B opened by first to third openings O1, O2, and O1′.

First to third light emitting laminates LC1′, LC2′, and LC1′ may be formed in the first to third openings O1, O2, and O1′, respectively. Since the first and third active layers 114a and 114a′ are formed from openings O1 and O1′ having the same width, the active layers may include first and third quantum well layers emitting light (e.g., blue light) of the same wavelength. Since the second active layer 114b is formed in the openings O2 having a relatively small width, the second active layer 114b may include second quantum well layers emitting light (e.g., green light) of a relatively long wavelength. Each of the first and third quantum well layers may emit light having a wavelength of 440 nm to 480 nm, and the second quantum well layer may emit light having a wavelength of 510 nm to 550 nm.

Thereafter, referring to FIG. 12C, the mask pattern 105 may be removed from the first conductivity-type semiconductor base layer 111B, and, referring to FIG. 12D, each edge region DL1, DL2, and DL1 of the first to third light emitting laminates LC1′, LC2′, and LC1′ may be removed.

After removing the mask pattern 105, two first light emitting laminates LC1′ and the second light emitting laminate LC2′ therebetween may remain on the first conductivity-type semiconductor base layer 111B. As described above, each of the first and third light emitting laminates LC1′ and LC2′ may include a damaged edge region. In some example embodiments, after removing the edge regions DL1 and DL2, two first LED cells LC1 and a second LED cell LC2 having the same width (W1=W2=W3) may be obtained. The three LED cells LC1, LC2, and LC1 may be maintained with the same pitch (P1=P2), and may be provided as light sources for the first to third sub-pixel, respectively.

The LED module (100E) provided as a pixel may include first LED cells LC1 and a second LED cell LC2, and the two first LED cells LC1 may emit light of a first color (e.g., blue), and the second LED cell LC2 may emit light of a second color (e.g., green). In some example embodiments, one of the two LED cells LC1 may form a wavelength converter (see “160R” in FIG. 13) emitting light of a third color (e.g., red).

FIG. 13 is a cross-sectional diagram illustrating a display apparatus according to some example embodiments, corresponding to the cross-section in FIG. 3.

Referring to FIG. 13, the display apparatus 10A according to some example embodiments may be configured similarly to the display apparatus 10 illustrated in FIGS. 3 to 4B other than the configuration in which the LED module obtained from the process in FIG. 12D may be employed, and the configuration in which the partition structure 170P is formed of a separate material. Components having the same reference designators may be understood by referring to descriptions of the same or similar components of the display apparatus 10 illustrated in FIGS. 1 to 4B unless otherwise indicated, and repeated description thereof is omitted for conciseness.

In some example embodiments, by polishing the under-semiconductor layer, a portion of regions including the first conductivity-type semiconductor base layer 111B may remain, and the partition structure 170P may be disposed on the polished surface of the remaining regions. The partition structure 170P in some example embodiments may include a structure formed of another material (e.g., a light blocking material or a reflective material). For example, the partition structure 170P may include a reflective metal material. The partition structure 170P may provide partitions for preventing light interference between the sub-pixels SP1, SP2, and SP3.

The LED module 100E employed in the pixel array 100 in some example embodiments may be manufactured from the processes in FIGS. 12A to 12D. The LED module (100E) provided as a pixel may include two first LED cells LC1 and a second LED cell LC2. Here, one of the two first LED cells LC1 may emit light of a first color (e.g., blue), and the second LED cell LC2 may emit light of a second color (e.g., green). A transparent resin layer 160 may be disposed in each sub-pixel space corresponding to the first LED cell LC1 for blue and the second LED cell LC2 for green. In some example embodiments, one of the two LED cells LC1 may form a wavelength converter 160R emitting light of a third color (e.g., red). The wavelength converter 160R in some example embodiments may include a resin layer in which red phosphors or red quantum dots are mixed.

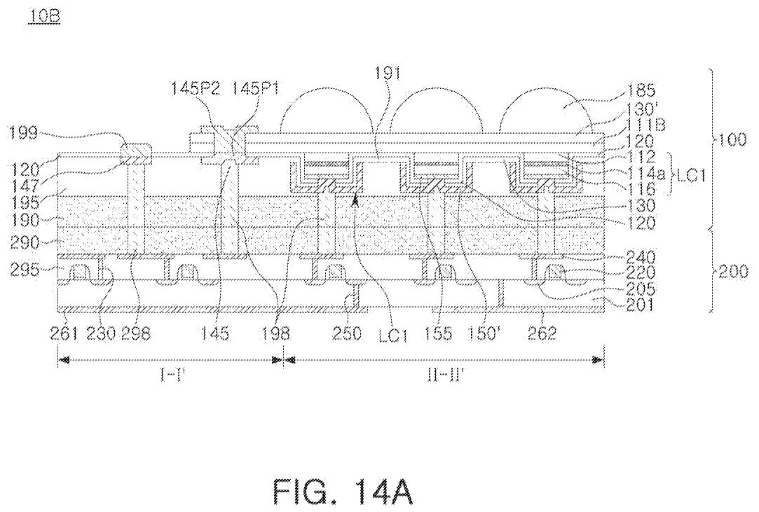

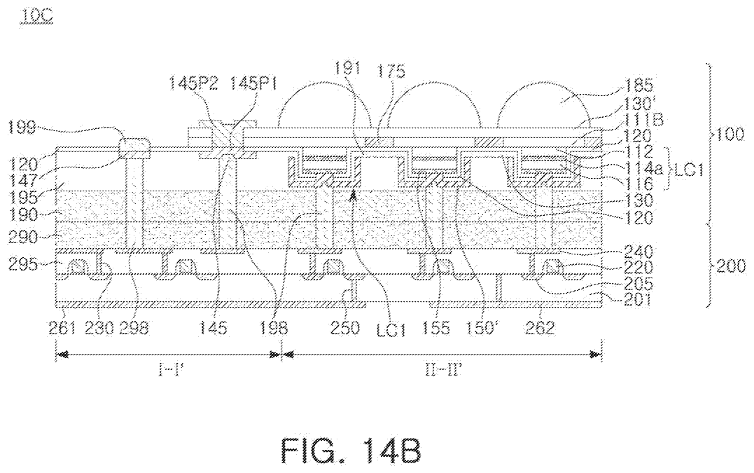

In the above-described display apparatus, a partition structure for dividing sub-pixels may be included, but the display apparatus may be implemented without the partition structure. FIGS. 14A and 14B are cross-section diagrams illustrating a display apparatus according to example embodiments, illustrating an example without a partition structure.

Referring to FIG. 14A, the display apparatus 10B according to some example embodiments may be configured similarly to the display apparatus 10 illustrated in FIGS. 3 to 4B, other than the configuration in which the partition structure is not included, the configuration in which a transparent electrode layer 130′ may be included as a common electrode of each LED cell LC1, LC2, and LC3 on the upper surface of the first conductivity-type semiconductor base layer 111B, and the configuration in which the second electrode 150′ may be formed in a bell-shape structure to reinforce a reflective function. Components having the same reference designators may be understood by referring to descriptions of the same or similar components of the display apparatus 10 illustrated in FIGS. 1 to 4B unless otherwise indicated, and repeated description thereof is omitted for conciseness.

In some example embodiments, by polishing the under-semiconductor layer, a portion of regions including the first conductivity-type semiconductor base layer 111B may remain, and a transparent electrode layer 130 may be disposed on the polished surface of the remaining regions. The remaining first conductivity-type semiconductor base layer 111B may have a sufficiently thin thickness to prevent light leakage between sub-pixels. For example, the thickness of the remaining first conductivity-type semiconductor base layer 111B may be 500 nm or less.

A transparent electrode layer 130′ may be formed on the upper surface (polished surface) of the remaining first conductivity-type semiconductor base layer 111B. For example, the transparent electrode layer 130′ may include a transparent conductive oxide (TCO) such as ITO, IZO, or GAZO. In some example embodiments, the transparent electrode layer 130′ may be provided as a common electrode of the LED cells LC1, LC2, and LC3. The transparent electrode layer 130′ may extend to the peripheral area PA, that is, the connection region CR disposed externally of the pixels PX, and the extended portion of the transparent electrode layer 130′ may be connected to the second common electrode pad 145P2 on the other side by the first common electrode pad 145P1 and may be connected to the circuit board 200 through the first bonding electrode 198.

The second electrode 150′ in some example embodiments may have a bell-shape structure formed of a reflective electrode material. The base insulating layer 191 may be relatively conformally formed on the passivation layer 120, and a second electrode 130′ electrically connected to the LED cell may be formed on the base insulating layer 191. The second electrode 150′ may have a bell-shape structure surrounding upper and side regions of each of the LED cells LC1, LC2, and LC3 along the surface of the base insulating layer 191. The second electrode 150′ may be a reflective structure and may improve brightness of each sub-pixels SP1, SP2, and SP3. The base insulating layer 191 may contribute to allowing the second electrode 150′ to have rounded corners. In some example embodiments, the base insulating layer 191 may not be provided when present in the passivation layer 120. The base insulating layer 191 may include the same or similar material as that of the wiring insulating layer 195 formed to cover the second electrode 150′.

Referring to FIG. 14B, the display apparatus 10C according to some example embodiments may be configured similarly to the display apparatus 10B illustrated in FIG. 14A other than the configuration in which the display apparatus 10C may further include a grid-shaped electrode layer together with a transparent electrode layer 130′. Components having the same reference designators may be understood by referring to descriptions of the same or similar components of the display apparatus 10B illustrated in FIG. 14A unless otherwise indicated, and repeated description thereof is omitted for conciseness.

In some example embodiments, by polishing the under-semiconductor layer, a portion of regions including the first conductivity-type semiconductor base layer 111B may remain, and a transparent electrode layer 130 may be disposed on the polished surface of the remaining regions. In some example embodiments, a reflective electrode layer 175 may be included on a region overlapping a region between the LED cells LC1, LC2, and LC3 in the remaining first conductivity-type semiconductor base layer 111B. On a plane, the overlapping region may have a grid shape, and the reflective electrode layer 175 may also have a grid shape. In some example embodiments, by forming the reflective electrode layer 175 after removing at least a portion of the overlapping region of the remaining first conductivity-type semiconductor base layer 111B, light leakage between sub-pixels may be effectively prevented.

The reflective electrode layer 175 may be connected to the transparent electrode layer 130′ and may be used as a portion of the common electrode structure of the LED cells LC1, LC2, and LC3. As such, in some example embodiments, the grid-shaped reflective electrode layer 175 may uniformly supply current to the entirety of the sub-pixels in the entire area of the display. In some example embodiments, the reflective electrode layer 175 may extend to the peripheral area PA, that is, the connection region CR disposed externally of the pixels PX, and the extended portion of the reflective electrode layer 175 may be connected to the second common electrode pad 145P2 on the other side by the first common electrode pad 145P1 and may be connected to the circuit board 200 through the first bonding electrode 198.

FIGS. 15A to 15F are cross-section diagrams illustrating a portion of processes of a method of manufacturing a display apparatus according to some example embodiments, illustrating a method of manufacturing the display apparatus in FIG. 3. The portion of processes may include manufacturing a pixel array substrate and bonding a pixel array substrate to a circuit board.

Referring to FIG. 15A, an under-semiconductor layer 111 having a first conductivity-type semiconductor base layer 111b, a first conductivity-type semiconductor cap layer 112, first to third active layer 114a, 114b, and 114c, and a second conductivity-type semiconductor layer 116 may be formed in order on a growth substrate 101, and the contact layer 155 may be formed.

The growth substrate 101 may be for growing a nitride single crystal, and may include, for example, at least one of sapphire, Si, SiC, MgAl₂O₄, MgO, LiAlO₂, LiGaO₂, and GaN. In some example embodiments, to improve crystallinity and light extraction efficiency of semiconductor layers, the growth substrate 101 may have an uneven structure on at least a portion of an upper surface thereof. In this case, the uneven structure may also be transferred to the layers grown thereon.

The under-semiconductor layer 111, the first conductivity-type base semiconductor layer 111B, the first to third active layer 114a, 114b, and 114c, and the second conductivity-type semiconductor layer 116 may be formed using, for example, metal organic chemical vapor deposition (MOCVD), hydride vapor phase epitaxy (HVPE), or molecular beam epitaxy (MBE) process.

The under-semiconductor layer 111 may include a first conductivity-type semiconductor base layer 111B and a first conductivity-type semiconductor layer or an undoped semiconductor layer therebelow. In some example embodiments, the under-semiconductor layer 111 may include a buffer layer and an undoped nitride layer (e.g., GaN). In the case, the buffer layer may be for mitigating lattice defects of the first conductivity-type semiconductor cap layer 112 and may include undoped nitride semiconductors such as undoped GaN, undoped AlN, and undoped InGaN. The first conductivity-type semiconductor base layer 111B and first conductivity-type semiconductor cap layer 112 may be an n-type nitride semiconductor layer such as n-type GaN, and the second conductivity-type semiconductor layer 116 may be a p-type nitride semiconductor layer such as p-type GaN/p-type AlGaN. The first to third active layers 114a, 114b, and 114c may have a single quantum well structure or a multiple quantum well structure such as InGaN/GaN. The contact layer 155 may be formed on the second conductivity-type semiconductor layer 116. For example, the contact layer 155 may be a highly reflective ohmic contact layer.

Thereafter, referring to FIG. 15B, a passivation layer 120 may be formed on the first to third LED cells LC1, LC2, and LC3, and a portion of the under-semiconductor layer 111 may be formed in the outer region ISO.

The passivation layer 120 may be formed on the upper surface of the stack structure with a uniform thickness, and may be removed from a portion of regions, which may be regions in which the first reflective electrode 130 (see FIG. 3) is to be formed. The passivation layer 120 may include, for example, at least one of SiO₂, SiN, SiCN, SiOC, SiON and SiOCN. The passivation layer 120 may be conformally formed, and accordingly, the passivation layer 120 may have a substantially uniform thickness. Openings for a first reflective electrode 130 and a common electrode 145 to be formed in a subsequent process may be formed.

In the outer region ISO, the under-semiconductor layer 111 may be removed to a predetermined depth. The outer region ISO may be cut-out in a subsequent process and may be a region for dividing modules. Accordingly, to prevent cracks in the cutting or dicing process, a portion of the under-semiconductor layer 111 may be removed in this process.

Thereafter, referring to FIG. 15C, a first electrode 130, a common electrode 145, and a first pad electrode 147 may be formed.

First, a first reflective electrode 130 may be formed on the passivation layer 120 and the first conductivity-type semiconductor layer 112. The first electrode 130 may have a substantially uniform thickness. The first electrode 130 may be formed in a region in which the pixels PX in FIG. 3 are disposed and a connection region (CR in FIG. 3).

Thereafter, the common electrode 145 and the first pad electrode 147 may be formed in the connection region CR and the pad regions PAD in FIG. 3, respectively. The common electrode 145 may be formed on the first reflective electrode 130 and the first pad electrode 147 may be formed on the passivation layer 120. The common electrode 145 and the first pad electrode 147 may be formed together through the same process. The first electrode 130, the common electrode 145, and the first pad electrode 147 may include a conductive material, for example, metal.

Thereafter, referring to FIG. 15D, a first wiring insulating layer 195 may be formed, and second electrodes 150 connected to the contact layers 155 may be formed.

The first wiring insulating layer 195 may be formed to cover the entirety of the structures formed in the previous processes, including the first electrode 130, and a process of planarizing the first wiring insulating layer 195 may be performed using a planarization process such as a chemical mechanical polishing (CMP) process or an etch-back process. For example, the first wiring insulating layer 195 may be a low dielectric material such as silicon oxide.

A first wiring insulating layer 195 may be additionally formed, contact holes penetrating through the first wiring insulating layer 195 and the passivation layer 120 and exposing the contact layers 155 may be formed, and contact layers 155 may be formed by filling the contact holes with a conductive material. A portion of the contact layers 155 may extend to an upper surface of the first wiring insulating layer 195.

Referring to FIG. 15E, a first bonding insulating layer 190 may be formed on second electrodes 150, and first bonding electrodes 198 may be formed.

The first bonding insulating layer 190 may include a material the same as or different from that of the first wiring insulating layer 195. In some example embodiments, the first bonding insulating layer 190 may include a material different from that of the first wiring insulating layer 195. The first bonding electrodes 198 may be formed by forming via holes penetrating through the first bonding insulating layer 190 and the first wiring insulating layer 195 and filling the via holes with a conductive material. The first bonding electrodes 198 may be connected to the second electrodes 150, the common electrode 145, and the first pad electrode 147.

Referring to FIG. 15F, a pixel array structure including first to third LED cells LC1, LC2, and LC3 may be bonded to the circuit board 200.

The circuit board 200 may be prepared through a separate process. The pixel array structure and the circuit board 200 may be bonded to each other on the wafer level by a wafer bonding method, for example, the hybrid bonding described above. The second bonding electrodes 298 may be bonded to the first bonding electrodes 198, and the second bonding insulating layer 290 may be bonded to the first bonding insulating layer 190. Accordingly, the structure including the LED cells 110 and the circuit board 200 may be bonded without an adhesive layer.

FIGS. 16A to 16D are cross-sectional diagrams illustrating a portion of processes of a method of manufacturing a display apparatus according to some example embodiments, illustrating processes subsequent to the process in FIG. 15F.

Referring to FIG. 16A, the growth substrate 101 may be removed from the under-semiconductor layer 111, and a portion of the under-semiconductor layer 111 may be removed. In the drawings, for ease of description, a pixel array structure including first to third LED cells LC1, LC2, and LC3 may be bonded to the circuit board 200.

The growth substrate 101 may be removed by various processes such as laser lift-off, mechanical polishing or mechanical chemical polishing, and an etching process. The under-semiconductor layer 111 may be partially removed to reduce to a predetermined thickness using, for example, a polishing process such as CMP. The under-semiconductor layer 111 may be removed such that the under-semiconductor layer 111 may not remain in the peripheral area (ISO in FIG. 3).

Thereafter, referring to FIG. 16B, a partition structure 111P defining sub-pixel spaces OP1, OP2, and OP3 may be formed using the under-semiconductor layer 111.

The partition structure 111P may be formed using an etching process for forming openings in regions corresponding to the first to third LED cells LC1, LC2, and LC3 in the under-semiconductor layer 111. The openings may provide first to third sub-pixels (SP1, SP2, and SP3 in FIG. 3) as corresponding first to third sub-pixel spaces (OP1, OP2, and OP3), respectively.

In some example embodiments, the first conductivity-type semiconductor base layer 111B may be shared by first to third LED cells LC1, LC2, and LC3. That is, first to third LED cells LC1, LC2, and LC3 may be connected to each other by the first conductivity-type semiconductor base layer 111B.

Thereafter, referring to FIG. 16C, a partition reflective layer 170 may be formed on the partition structure 111B.

The first partition insulating film 172 and the reflective metal film 174 may be formed, and the reflective metal film 174 portion may be removed from the bottom surfaces of the first to third sub-pixel space OP1, OP2, and OP3, and a second partition insulating film 176 may be formed, thereby forming a partition reflective layer 170.

Thereafter, referring to FIG. 16D, transparent resin portions 160 and a planarization layer 182 may be formed in the first to third sub-pixel space OP1, OP2, and OP3, and microlenses 185 may be formed on planarization layer 182.

A transparent resin portion 160 formed of a transparent resin may be formed on the first to third sub-pixel space OP3. The transparent resin used in the process may include, for example, a transparent resin such as a silicone resin or an epoxy resin.

In some example embodiments, an opening may be formed by removing the under-semiconductor layer 111 and the first conductivity-type semiconductor layer 112 from the first pad electrode 147. The opening may be formed to expose the passivation layer 120 on the first pad electrode 147 in the pad regions PAD in FIG. 3. Thereafter, the passivation layer 120 exposed through the opening portion OT may be partially removed, the second pad electrode 199 may be formed, and adjacent modules may be diced in the outer region ISO, thereby manufacturing the display apparatus 10 (see FIG. 3).

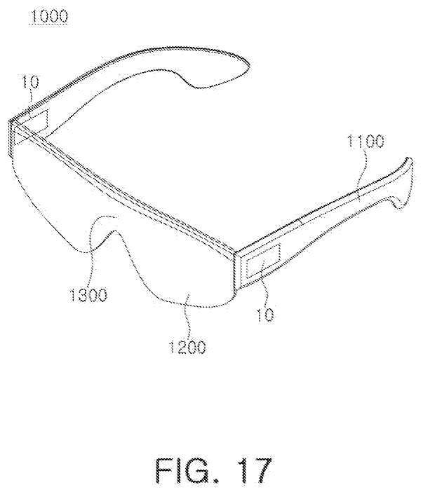

FIG. 17 is a diagram illustrating an electronic device including a display apparatus according to some example embodiments.

Referring to FIG. 17, an electronic device 1000 according to some example embodiments may be a glasses-type display which may be a wearable device. The electronic device 1000 may include a pair of temples 1100, a pair of light coupling lenses 1200, and a bridge 1300. The electronic device 1000 may further include a display apparatus 10 including an image generator.

The electronic device 1000 may be implemented as a head-mounted, glasses-type, or goggles-type virtual reality (VR) device for providing virtual reality or providing virtual images and external real scenery together, an augmented reality (AR) device, or a mixed reality (MR) device.

The temples 1100 may extend in one direction. The temples 1100 may be spaced apart from each other and may extend in parallel. The temples 1100 may be folded toward the bridge 1300. The bridge 1300 may be provided between the light coupling lenses 1200 and may connect the light coupling lenses 1200 to each other. The light coupling lenses 1200 may include a light guide plate. The display apparatus 10 may be disposed on each of the temples 1100 and may generate an image on the light coupling lenses 1200. The display apparatus 10 may be implemented as a display apparatus according to the aforementioned example embodiments.

According to the aforementioned example embodiments, since LED cells emitting light of different wavelengths may be simultaneously grown on the same substrate, an LED module for a display may be manufactured in a simplified manner. Also, the shape of the LED cells included in each sub-pixel may be controlled through a process of selectively removing edge regions causing leakage current in each LED cell.

While various example embodiments have been illustrated and described above, it will be configured as apparent to those skilled in the art that modifications and variations could be made without departing from the scope of the present disclosure as defined by the appended claims.

1. A method comprising:
forming a first conductivity-type semiconductor base layer on a growth substrate;
forming a mask pattern on the first conductivity-type semiconductor base layer, wherein the mask pattern has a first opening, a second opening and a third opening having different widths, and the first opening, the second opening and the third opening are arranged with a same pitch;
simultaneously forming a first light emitting laminate, a second light emitting laminate, and a third light emitting laminate in the first opening, the second opening, and the third opening, respectively, by sequentially growing a first active layer, a second active layer, and a third active layer and second conductivity-type semiconductor layers on regions of the first conductivity-type semiconductor base layer opened by the first opening, the second opening, and the third opening, respectively;
removing the mask pattern from the first conductivity-type semiconductor base layer; and
removing an edge region of each of the first light emitting laminate, the second light emitting laminate, and the third light emitting laminate,
wherein forming the first light emitting laminate, the second light emitting laminate, and the third light emitting laminate is performed by a same growth process, and the first active layer, the second active layer, and the third active layer have a first quantum well layer, a second quantum well layer, and a third quantum well layer emitting light of different wavelengths, respectively.

2. The method of claim 1, wherein the first opening has a first width, the second opening has a second width, and the third opening has a third width, and the first width is greater than the second width, and the second width is greater than the third width.

3. The method of claim 2, wherein the first quantum well layer emits light having a wavelength of 440 nm to 480 nm, the second quantum well layer emits light having a wavelength of 510 nm to 550 nm, and the third quantum well layer emits light having a wavelength of 610 nm to 650 nm.

4. The method of claim 1,
wherein the first light emitting laminate, the second light emitting laminate, and the third light emitting laminate include a nitride single crystal laminate, and
wherein the first quantum well layer, the second quantum well layer, and the third quantum well layer include nitride single crystal layers satisfying InₓGa₁₋ₓN having different contents of indium (x), respectively.

5. The method of claim 4,
wherein the first opening has a first area, the second opening has a second area, and the third opening has a third area, and the first area is larger than the second area, and the second area is larger than the third area, and
wherein a content of indium of the first quantum well layer is in a range of 0.15 to 0.2, a content of indium of the second quantum well layer is in a range of 0.25 to 0.3, and a content of indium of the third quantum well layer is in a range of 0.3 to 0.35.

6. The method of claim 5, wherein the first quantum well layer has a first thickness, the second quantum well layer has a second thickness, and the third quantum well layer has a third thickness, and the first thickness is greater than the second thickness, and the second thickness is greater than the third thickness.

7. The method of claim 1, wherein forming the first light emitting laminate, the second light emitting laminate, and the third light emitting laminate includes growing first conductivity-type semiconductor cap layers on the regions of the first conductivity-type semiconductor base layer, respectively, before growing the first active layer, the second active layer, and the third active layer.

8. The method of claim 1,
wherein each of the first light emitting laminate, the second light emitting laminate, and the third light emitting laminate includes a nitride single crystal laminate having an upper surface which is a (0001) plane, and
wherein the edge region of each of the first light emitting laminate, the second light emitting laminate, and the third light emitting laminate includes an inclined side surface region.

9. The method of claim 1, wherein removing the edge region includes removing edge regions having different widths from the first light emitting laminate, the second light emitting laminate, and the third light emitting laminate such that the first light emitting laminate, the second light emitting laminate, and the third light emitting laminate have the same width after removing the edge region.

10. The method of claim 1, wherein the first light emitting laminate, the second light emitting laminate, and the third light emitting laminate have different widths after the removing the edge region.

11. The method of claim 1, further comprising:
forming a first electrode layer, a second electrode layer, and a third electrode layer on upper surfaces of the first light emitting laminate, the second light emitting laminate, and the third light emitting laminate, respectively, to be connected to the second conductivity-type semiconductor layers; and
forming a common electrode connected to the first conductivity-type semiconductor base layer.

12. A method comprising:
forming a first conductivity-type semiconductor base layer on a growth substrate;
forming a first mask pattern on the first conductivity-type semiconductor base layer, wherein the first mask pattern has a first opening and a second opening having different widths, and the first opening and the second opening are arranged with a first pitch;
simultaneously growing a first active layer and a second active layer on a first region and a second region of the first conductivity-type semiconductor base layer opened by the first opening and the second opening, respectively, wherein the first active layer and the second active layer respectively include a first quantum well layer and a second quantum well layer emitting a first light and a second light of different wavelengths, respectively;
forming a second mask pattern covering the first opening and the second opening, the second mask pattern having a third opening configured to open a third region of the first conductivity-type semiconductor base layer, wherein the third opening is arranged with a second pitch with an adjacent opening among the first opening and the second opening, and the second pitch is the same as the first pitch;
forming a third active layer in the third region of the first conductivity-type semiconductor base layer, wherein the third active layer includes a third quantum well layer configured to emit third light of a wavelength different from wavelengths of each of the first light and the second light;
forming a fourth opening and a fifth opening exposing the first active layer and the second active layer, respectively, in the second mask pattern;
forming a first light emitting laminate, a second light emitting laminate, and a third light emitting laminate by growing a second conductivity-type semiconductor layer on each of the first active layer, the second active layer, and the third active layers;
removing the first mask pattern and the second mask pattern from the first light emitting laminate, the second light emitting laminate, and the third light emitting laminate and the first conductivity-type semiconductor base layer; and
removing an edge region of each of the first light emitting laminate, the second light emitting laminate, and the third light emitting laminate.

13. The method of claim 12, wherein the first opening has a first area and the second opening has a second area, and the first area is larger than the second area.

14. The method of claim 13, wherein a content of indium of the first quantum well layer is in a range of 0.15 to 0.2, and a content of indium of the second quantum well layer is in a range of 0.25 to 0.3.

15. The method of claim 13, wherein the third opening has a third area, and the third area is equal to the second area.

16. The method of claim 12, wherein the first quantum well layer emits light having a wavelength of 440 nm to 480 nm, the second quantum well layer emits light having a wavelength of 510 nm to 550 nm, and the third quantum well layer emits light having a wavelength of 610 nm to 650 nm.

17. A method comprising:
forming a first conductivity-type semiconductor base layer on a growth substrate;
forming a mask pattern having a first opening, a second opening, and a third opening arranged with a same pitch on the first conductivity-type semiconductor base layer, wherein the first opening has a first width, the second opening has a second width, and the third opening has a third width, and the first width is greater than the second width, and the first width is the same as the third width;
forming a first light emitting laminate, a second light emitting laminate, and a third light emitting laminate in the first opening, the second opening, and the third opening, respectively, by sequentially growing a first active layer, a second active layer, and a third active layer and second conductivity-type semiconductor layers on regions of the first conductivity-type semiconductor base layer opened by the first opening, the second opening, and the third opening, respectively;
removing the mask pattern from the first conductivity-type semiconductor base layer; and
removing an edge region of each of the first light emitting laminate, the second light emitting laminate, and the third light emitting laminate,
wherein forming the first light emitting laminate, the second light emitting laminate, and the third light emitting laminate is performed by a same growth process, the first active layer and the third active layer include a first quantum well layer and a third quantum well layer emitting light of a same wavelength, respectively, and the second active layer includes a second quantum well layer configured to emit light of a different wavelength from the same wavelength of the first quantum well layer and the third quantum well layer.

18. The method of claim 17, wherein each of the first quantum well layer and the third quantum well layer emits light having a wavelength of 440 nm to 480 nm, and the second quantum well layer emits light having a wavelength of 510 nm to 550 nm.

19. The method of claim 17, further comprising:
forming a first electrode layer, a second electrode layer, and a third electrode layer on upper surfaces of the first light emitting laminate, the second light emitting laminate, and the third light emitting laminate, respectively, to be connected to the second conductivity-type semiconductor layers; and
forming a common electrode connected to the first conductivity-type semiconductor base layer.

20. The method of claim 17, further comprising:
forming a wavelength converter configured to convert light emitted from the third quantum well layer on the third light emitting laminate.

21-26. (canceled)
